(19) United States
(12) Patent Application Publication
(10) Pub. No.: US 2024/0346222 A1
(43) Pub. Date: Oct. 17, 2024

(54) ELECTRONIC DEVICE SUPPORTING MANUFACTURE OF SEMICONDUCTOR DEVICE AND OPERATING METHOD OF ELECTRONIC DEVICE

(71) Applicant: Samsung Electronics Co., Ltd., Suwon-si (KR)

(72) Inventors: Jiho Han, Suwon-si (KR); Jong-Seong Kim, Suwon-si (KR); Sungju Jang, Suwon-si (KR); Hyuckjoon Kwon, Suwon-si (KR); Sunghoon Kim, Suwon-si (KR); Raehyun Song, Suwon-si (KR)

(21) Appl. No.: 18/510,969

(22) Filed: Nov. 16, 2023

(30) Foreign Application Priority Data
Apr. 11, 2023 (KR) 10-2023-0047675
Jun. 2, 2023 (KR) 10-2023-0071803

(51) Int. Cl. G06F 30/392

(52) U.S. Cl. CPC G06F 30/392

(57) ABSTRACT

Disclosed is an operating method of an electronic device that includes a processor and supports manufacture of a semiconductor device. The operating method includes receiving, at the processor, circuit schematics for the manufacture of the semiconductor device, partitioning, at the processor, circuit components of the circuit schematics into at least two mats, calculating, at the processor, availability of placement and routing of the circuit components, based on limited connecting elements electrically connected to the circuit components, for each of the at least two mats, and performing, at the processor, the placement and routing to generate a layout image for the manufacture of the semiconductor device when the availability indicates that the placement and routing is available. The limited connecting elements include vertical lines, which electrically connect an upper portion and a lower portion of the semiconductor device, at limited locations of the semiconductor device.

### CROSS-REFERENCE TO RELATED APPLICATIONS

This application claims priority under 35 U.S.C. § 119 to Korean Patent Application Nos. 10-2023-0047675 filed on Apr. 11, 2023, and 10-2023-0071803 filed on Jun. 2, 2023, in the Korean Intellectual Property Office, the disclosures of which are incorporated by reference herein in their entireties.

### BACKGROUND

Embodiments of the present disclosure described herein relate to an electronic device, and more particularly, relate to an electronic device supporting the manufacture of a semiconductor device such that a time necessary to generate a layout image decreases and an operating method of the electronic device.

To manufacture a semiconductor device, circuit schematics designed to perform target functions may be generated. When the circuit schematics are completed, a layout image for manufacturing a semiconductor device by using the circuit schematics may be generated. The circuit schematics show only electrical connections of components of the semiconductor device, but the layout image shows lines (or wires) connecting the components of the semiconductor device.

The process of generating the layout image from the circuit schematics based on the lines may be called “placement and routing (PnR)”. When the layout image generated from the circuit schematics through the placement and routing violates limits applied to the process of manufacturing a semiconductor device, the layout image is incapable of being used to manufacture the semiconductor device.

### SUMMARY

Embodiments of the present disclosure provide an electronic device capable of decreasing a time necessary to generate a layout image by verifying, in advance, whether a layout image to be generated through the placement and routing violates limits applied to the process of manufacturing a semiconductor device and an operating method of the electronic device.

According to some embodiments, an operating method of an electronic device that includes a processor and is configured to support manufacture of a semiconductor device includes receiving, at the processor, circuit schematics for the manufacture of the semiconductor device, partitioning, at the processor, circuit components of the circuit schematics into at least two mats, calculating, at the processor, availability of placement and routing (PnR) of the circuit components, based on limited connecting elements that are configured to be electrically connected to the circuit components, for each of the at least two mats, and performing, at the processor, the placement and routing to generate a layout image for the manufacture of the semiconductor device when the availability of the placement and routing that was calculated indicates that the placement and routing is available. The limited connecting elements include vertical lines, which are configured to electrically connect an upper portion and a lower portion of the semiconductor device, at limited locations of the semiconductor device.

According to some embodiments, an operating method of an electronic device that includes a processor and is configured to support manufacture of a semiconductor device includes receiving, at the processor, circuit schematics for the manufacture of the semiconductor device, partitioning, at the processor, circuit components of the circuit schematics into at least two mats, calculating, at the processor, availability of placement and routing (PnR) of the circuit components, based on limited connecting elements that are configured to be electrically connected to the circuit components, for each of the at least two mats, performing, at the processor, the placement and routing to generate a layout image for the manufacture of the semiconductor device when the availability of the placement and routing that was calculated indicates that the placement and routing is available, and ungrouping one of the circuit components to a lower level when the availability of the placement and routing that was calculated indicates that the placement and routing is unavailable. The limited connecting elements include vertical lines, which are configured to electrically connect an upper portion and a lower portion of the semiconductor device, at limited locations of the semiconductor device, and calculating the availability of the placement and routing of the circuit components includes counting interconnections between the at least two mats.

According to some embodiments, an electronic device configured to support manufacture of a semiconductor device includes a processor, and a memory configured to store circuit schematics for the manufacture of the semiconductor device. The processor is configured to partition circuit components of the circuit schematics into at least two mats, calculate availability of placement and routing (PnR) of the circuit components, based on limited connecting elements that are configured to be electrically connected to the circuit components, for each of the at least two mats, and perform the placement and routing to generate a layout image for the manufacture of the semiconductor device when the availability of the placement and routing that was calculated indicates that the placement and routing is available. The limited connecting elements include vertical lines, which are configured to electrically connect an upper portion and a lower portion of the semiconductor device, at limited locations of the semiconductor device.

### BRIEF DESCRIPTION OF THE FIGURES

The above and other objects and features of the present disclosure will become apparent by describing in detail embodiments thereof with reference to the accompanying drawings.

FIG. 1 illustrates a semiconductor manufacturing system according to some embodiments of the present disclosure.

FIG. 2 is a block diagram illustrating an electronic device according to some embodiments of the present disclosure.

FIG. 3 illustrates an operating method of an electronic device according to some embodiments of the present disclosure.

FIG. 4 illustrates an example of a semiconductor device manufactured by a semiconductor manufacturing system of FIG. 1.

FIG. 5 illustrates an example in which a semiconductor device is manufactured in a COP method.

FIG. 6 illustrates an example of mats of a semiconductor device.

FIG. 7 illustrates an example of a layout generation module.

FIG. 8 illustrates an example of a method in which a partitioning module partitions circuit components.

FIG. 9 illustrates an example of circuit components of circuit schematics.

FIG. 10 illustrates an example in which a partitioning module partitions circuit schematics of FIG. 9 to generate first circuit schematics.

FIG. 11 illustrates an example of a method in which an availability calculation module calculates availability of first circuit schematics.

FIG. 12 illustrates an example of a method in which an ungroup module ungroups a circuit component of a current level.

FIG. 13 illustrates an example in which an ungroup module ungroups a circuit component.

FIG. 14 illustrates an example in which a partitioning module partitions circuit schematics of FIG. 13 to generate first circuit schematics.

FIG. 15 illustrates an example of a method in which a layout generation module optimizes a layout image.

FIG. 16 is a view for describing a semiconductor device according to some embodiments of the present disclosure.

FIG. 17 is a view illustrating a semiconductor device according to some embodiments of the present disclosure.

FIG. 18 illustrates an example of a method in which a semiconductor manufacturing system manufactures semiconductor devices.

### DETAILED DESCRIPTION

Below, example embodiments of the present disclosure will be described in detail and clearly to such an extent that one of ordinary skill in the art can easily carry out the present disclosure.

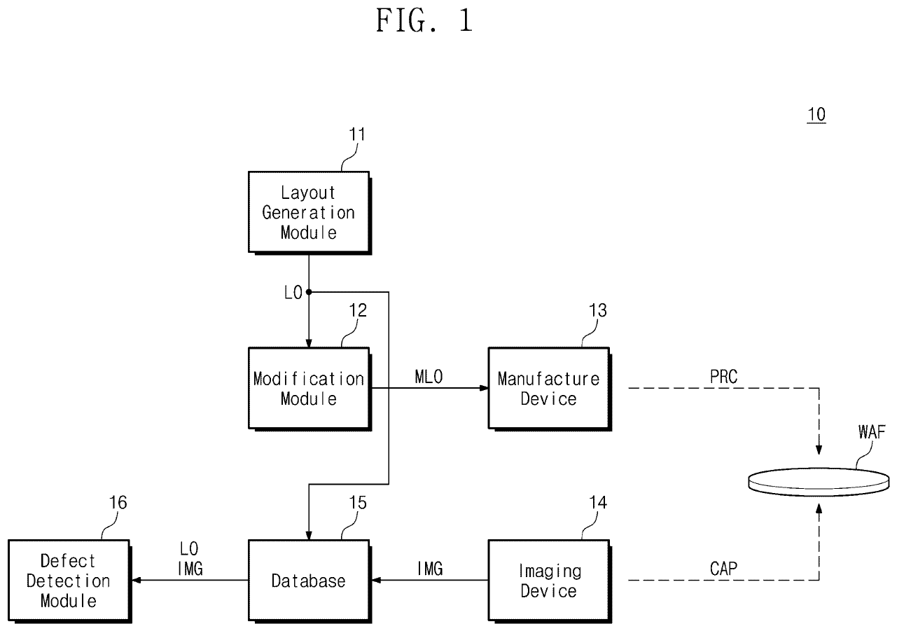

FIG. 1 illustrates a semiconductor manufacturing system 10 according to some embodiments of the present disclosure. Referring to FIG. 1, the semiconductor manufacturing system 10 may include a layout generation module 11, a modification module 12, a manufacture device 13, an imaging device 14, a database 15, and a defect detection module 16. The semiconductor manufacturing system 10 may manufacture semiconductor devices by using a wafer WAF.

The layout generation module 11 may generate a layout image LO. For example, the layout generation module 11 may generate or receive circuit schematics that are based on a circuit. The layout generation module 11 may generate the layout image LO by placing and routing standard cells based on the circuit schematics. Alternatively, after placing the standard cells, the layout generation module 11 may generate the layout image LO by modifying the standard cells or placing and routing specialization cells not included in the standard cells.

For example, the routing may include implementing electrical connections between components (e.g., including the standard cells and the modified cells) with lines (or wires). The routing may include placing via contacts connected to the components of the semiconductor device and placing metal lines in two or more metal layers connecting the via contacts. The process of generating the layout image LO from the circuit schematics may be called “placement and routing (PnR)”.

The modification module 12 may receive the layout image LO for the manufacture of new semiconductor devices from the layout generation module 11. In some embodiments, the modification module 12 may be trained to generate a modified layout image MLO from the layout image LO.

The modification module 12 may be trained to generate the modified layout image MLO from the layout image LO based on various factors capable of being caused in the process of manufacturing semiconductor devices; for example, the modification module 12 may be trained to generate the modified layout image MLO based at least on a process proximity correction (PPC) and an optical proximity correction (OPC).

For example, the optical proximity correction may be performed to correct distortions caused in photoresist patterns due to various factors, which include a feature of a light source, a feature of a photoresist, positional relationships between the light source and patterns formed in the photoresist, etc., in the process of generating a photomask for manufacturing a semiconductor device. The process proximity correction may be used to correct distortions caused during processes (e.g., an etching process) due to various factors including a feature of materials for performing a process, a feature of materials to which the process is applied, a feature of photoresist patterns, etc.

In some embodiments, the modification module 12 may be trained based on at least one of various machine learning algorithms, such as a neural network and a generative adversarial network (GAN), such that the modified layout image MLO is generated from the layout image LO.

The manufacture device 13 may receive the modified layout image MLO from the modification module 12. The manufacture device 13 may apply processes PRC to the wafer WAF based on the modified layout image MLO. For example, the processes PRC may include an etching process, a deposition process, a growth process, a planarization process, etc. As the processes PRC are applied to the wafer WAF, semiconductor devices may be formed in the wafer WAF.

The imaging device 14 may generate a captured image IMG by capturing an image of the semiconductor devices formed in the wafer WAF (refer to “CAP” of FIG. 1). For example, the imaging device 14 may include a scanning electron microscope (SEM).

The database 15 may receive the layout image LO from the layout generation module 11 and may receive the captured image IMG of the semiconductor devices manufactured based on the layout image LO from the imaging device 14. The database 15 may store and manage a pair of the layout image LO and the corresponding captured image IMG. In some embodiments, the database 15 may provide the layout image LO and the captured image IMG for the learning of the modification module 12. Also, the database 15 may store the circuit schematics for manufacturing semiconductor devices.

The defect detection module 16 may receive the layout image LO and the captured image IMG corresponding thereto from the database 15. The defect detection module 16 may detect defects of the semiconductor devices by comparing the layout image LO and the captured image IMG. That is, the defect detection module 16 may detect defects of the semiconductor devices by comparing a pre-image (e.g., the layout image LO) and a post-image (e.g., the captured image IMG) of the semiconductor devices.

In some embodiments, the layout generation module 11, the modification module 12, and the defect detection module 16 may be implemented by software executable by a processor, a processor designed to perform a relevant function, or a combination of hardware and software designed to perform a relevant function.

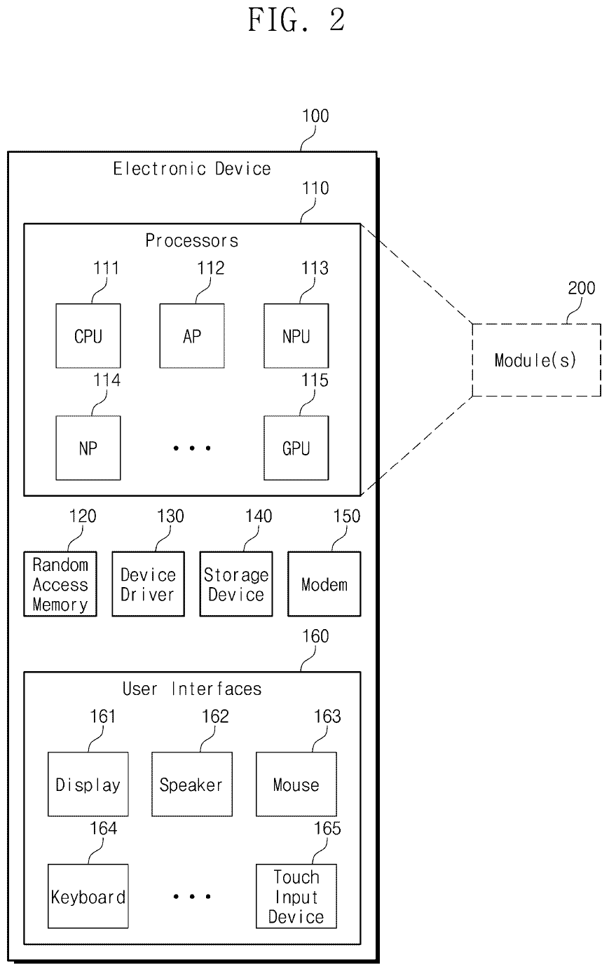

FIG. 2 is a block diagram illustrating an electronic device 100 according to some embodiments of the present disclosure. Referring to FIG. 2, the electronic device 100 may include processors 110, a random access memory 120, a device driver 130, a storage device 140, a modem 150, and user interfaces 160.

The processors 110 may include, for example, at least one general-purpose processor such as a central processing unit (CPU) 111 or an application processor (AP) 112. Also, the processors 110 may further include at least one special-purpose processor such as a neural processing unit (NPU) 113, a neuromorphic processor (NP) 114, or a graphics processing unit (GPU) 115. The processors 110 may include two or more homogeneous processors.

At least one of the processors 110 may be used to train a module(s) 200 or to execute the trained module(s) 200. At least one of the processors 110 may train or execute the module(s) 200 based on various data or information. For example, the module(s) 200 may be implemented in the form of instructions (or codes) that are executed by at least one of the processors 110. In this case, the at least one processor may load the instructions (or codes) of the module(s) 200 to the random access memory 120.

For another example, at least one (or at least another) processor among the processors 110 may be manufactured to implement the module(s) 200. For example, the at least one processor may be a dedicated processor that is implemented in hardware based on the module(s) 200 generated by the learning of the module(s) 200.

For another example, at least one (or at least another) processor among the processors 110 may be manufactured to implement various machine learning or deep learning modules. The at least one processor may implement the module(s) 200 by receiving information (e.g., instructions or codes) corresponding to the module(s) 200.

The random access memory 120 may be used as a working memory of the processors 110 and may be used as a main memory or a system memory of the electronic device 100. The random access memory 120 may include a volatile memory such as a dynamic random access memory or a static random access memory, or a nonvolatile memory such as a phase-change random access memory, a ferroelectric random access memory, a magnetic random access memory, or a resistive random access memory.

The device driver 130 may control the following peripheral devices depending on a request of the processors 110: the storage device 140, the modem 150, and the user interfaces 160. The storage device 140 may include a stationary storage device such as a hard disk drive or a solid state drive, or a removable storage device such as an external hard disk drive, an external solid state drive, or a removable memory card.

The modem 150 may provide remote communication with the external device. The modem 150 may perform wired or wireless communication with the external device. The modem 150 may communicate with the external device based on at least one of various communication schemes such as Ethernet, wireless-fidelity (Wi-Fi), long term evolution (LTE), and 5^{th} generation (5G) mobile communication.

The user interfaces 160 may receive information from the user and may provide information to the user. The user interfaces 160 may include at least one user output interface such as a display 161 or a speaker 162, and at least one user input interface such as a mouse 163, a keyboard 164, or a touch input device 165.

The instructions (or codes) of the module(s) 200 may be received through the modem 150 and may be stored in the storage device 140. The instructions (or codes) of the module(s) 200 may be stored in a removable storage device, and the removable storage device may be connected to the electronic device 100. The instructions (or codes) of the module(s) 200 may be loaded to the random access memory 120 from the storage device 140 so as to be executed thereon.

In some embodiments, the module(s) 200 may include at least one of the layout generation module 11, the modification module 12, or the defect detection module 16 described with reference to FIG. 1. The layout generation module 11, the modification module 12, and the defect detection module 16 may be implemented or executed in different electronic devices. At least two of the layout generation module 11, the modification module 12, and the defect detection module 16 may be implemented or executed in one electronic device.

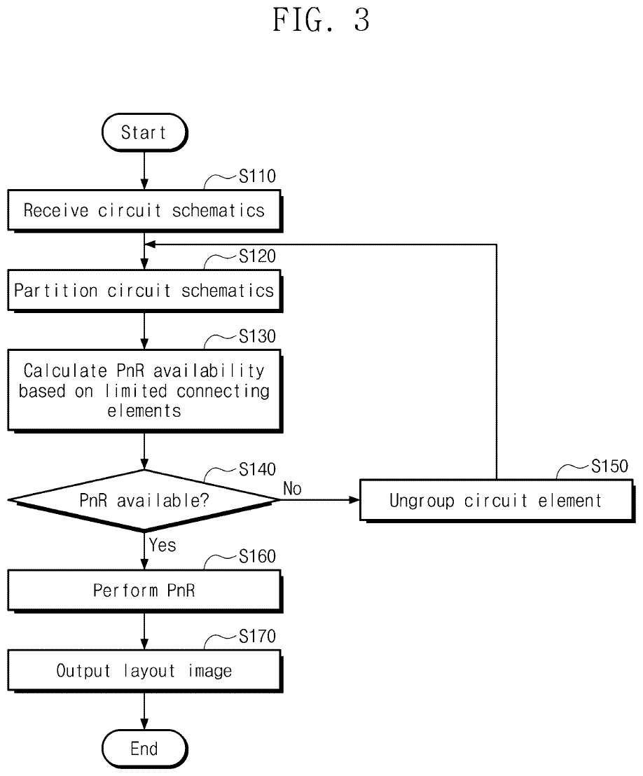

FIG. 3 illustrates an operating method of the electronic device 100 according to some embodiments of the present disclosure. Referring to FIGS. 1, 2, and 3, in operation S110, the electronic device 100 may receive the circuit schematics. For example, the layout generation module 11 of the module(s) 200 executed by the processors 110 of the electronic device 100 may receive the circuit schematics from the database 15.

In operation S120, the electronic device 100 may partition the circuit schematics. For example, the layout generation module 11 of the module(s) 200 executed by the processors 110 of the electronic device 100 may partition circuit components included in the circuit schematics, based on the limits applied to the process of manufacturing a semiconductor device.

In some embodiments, the circuit schematics may have a hierarchical structure including a plurality of levels. Circuit components present in the uppermost level may be regarded as circuit components of a current level. The circuit components of the uppermost level may include a circuit component of at least one lower level (also referred to as a lower-level circuit component) or may not include a circuit component of a lower level. A circuit component of the lowermost level may include at least one transistor, at least one diode, at least one resistor, at least one capacitor, or at least one inductor.

For example, due to the limits applied to the routing, the circuit schematics may have limits that the circuit schematics should be partitioned into at least two mats. In this case, the layout generation module 11 may partition the circuit components of the current level of the circuit schematics into at least two mats.

In operation S130, the electronic device 100 may calculate PnR availability based on limited connecting elements. For example, the layout generation module 11 of the module(s) 200 executed by the processors 110 of the electronic device 100 may calculate the PnR availability indicating whether the PnR of the limited connecting elements are possible while satisfying the limits applied to the limited connecting elements, based on the circuit components partitioned into at least two mats.

For example, the limited connecting elements may include vertical lines, which are configured to connect an upper portion and a lower portion of a semiconductor device, at limited locations of a semiconductor device manufactured based on the layout image LO. The limited connecting elements have limits that the limited connecting elements are capable of being implemented only at limited locations. That is, locations and the number of limited connecting elements may be limited. For example, in each of at least two mats, locations and the number of limited connecting elements may be limited. The layout generation module 11 may calculate the PnR availability for each of at least two mats.

In operation S140, the electronic device 100 may determine whether the PnR is available. For example, the layout generation module 11 of the module(s) 200 executed by the processors 110 of the electronic device 100 may determine whether the PnR availability calculated for each mat indicates that the PnR is available or that the PnR is unavailable.

When the PnR availability indicates that the PnR is unavailable (e.g., No in operation S140), in operation S150, the electronic device 100 may ungroup a circuit component (also referred to as a circuit element) to a lower level. For example, the layout generation module 11 of the module(s) 200 executed by the processors 110 of the electronic device 100 may ungroup the circuit component of the current level and may call circuit components of a lower level (i.e., lower-level circuit components) included in the circuit component to the current level. Afterwards, the electronic device 100 may again perform operation S120.

When the PnR availability indicates that the PnR is available (e.g., Yes in operation S140), in operation S160, the electronic device 100 may perform the PnR. For example, the layout generation module 11 of the module(s) 200 executed by the processors 110 of the electronic device 100 may generate the layout image LO by performing the PnR based on the circuit components partitioned into at least two mats such that the PnR is possible.

In operation S170, the electronic device 100 may output the layout image LO. For example, the layout generation module 11 of the module(s) 200 executed by the processors 110 of the electronic device 100 may output the generated layout image LO to the modification module 12.

As described above, the electronic device 100 according to some embodiments of the present disclosure may in advance determine whether the layout image LO to be generated by the PnR has the PnR availability, before performing the PnR. Accordingly, the issue that the layout image LO is incapable of being used due to the limits applied to the process of manufacturing a semiconductor device after the layout image LO is generated may be prevented, and the issue that a time taken to manufacture a semiconductor device increases may be prevented.

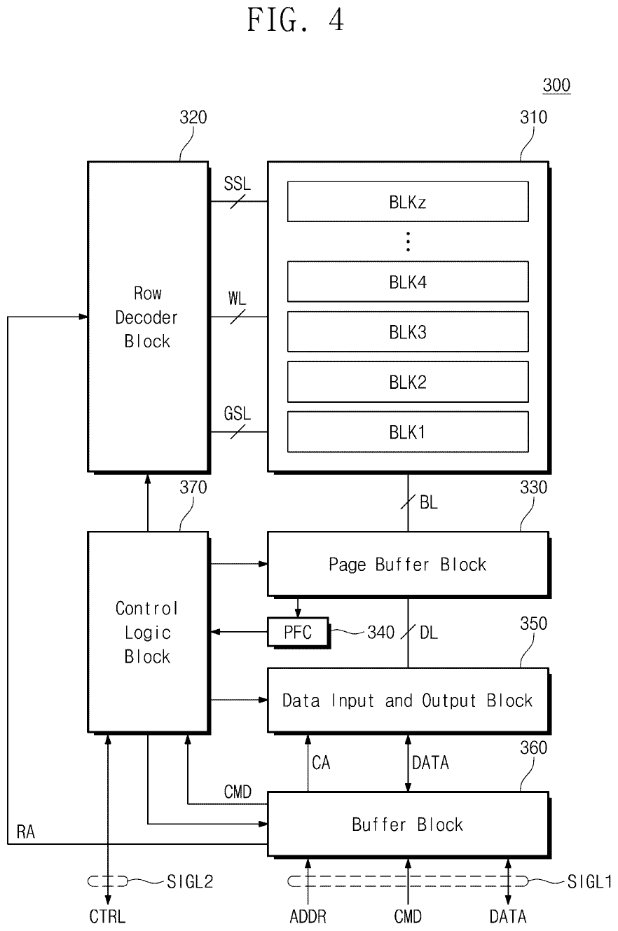

FIG. 4 is a diagram illustrating an example of a semiconductor device 300 manufactured by the semiconductor manufacturing system 10 of FIG. 1. For example, the semiconductor device 300 may include a volatile memory device such as a dynamic random access memory or a static random access memory or a nonvolatile memory device such as a NAND flash memory, a NOR flash memory, a phase-change memory, a ferroelectric memory, a magnetic memory, or a resistive memory.

Referring to FIG. 4, semiconductor device 300 includes a memory cell array 310, a row decoder block 320, a page buffer block 330, a pass/fail check block (PFC) 340, a data input and output block 350, a buffer block 360, and a control logic block 370.

The memory cell array 310 includes a plurality of memory blocks BLK1 to BLKz. Each of the memory blocks BLK1 to BLKz includes a plurality of memory cells. Each of the memory blocks BLK1 to BLKz may be connected to the row decoder block 320 through at least one ground selection line GSL, word lines WL, and at least one string selection line SSL. Some of the word lines WL may be used as dummy word lines. Each of the memory blocks BLK1 to BLKz may be connected to the page buffer block 330 through a plurality of bit lines BL. The plurality of memory blocks BLK1 to BLKz may be connected in common to the plurality of bit lines BL.

In some embodiments, each of the plurality of memory blocks BLK1 to BLKz may correspond to a unit of the erase operation. Memory cells belonging to each memory block may be erased at the same time. As another example, each of the memory blocks BLK1 to BLKz may be divided into a plurality of sub-blocks. Each of the plurality of sub-blocks may correspond to a unit of the erase operation.

The row decoder block 320 is connected to the memory cell array 310 through the ground selection lines GSL, the word lines WL, and the string selection lines SSL. The row decoder block 320 operates under control of the control logic block 370.

The row decoder block 320 may decode a row address RA received from the buffer block 360 and may control voltages to be applied to the string selection lines SSL, the word lines WL, and the ground selection lines GSL based on the decoded row address.

The page buffer block 330 is connected to the memory cell array 310 through the plurality of bit lines BL. The page buffer block 330 is connected to the data input and output block 350 through a plurality of data lines DL. The page buffer block 330 operates under control of the control logic block 370.

In the program operation, the page buffer block 330 may store data to be written in memory cells. The page buffer block 330 may apply voltages to the plurality of bit lines BL based on the stored data. In the read operation or in the verify read operation that is performed in the program operation or the erase operation, the page buffer block 330 may sense voltages of the bit lines BL and may store a sensing result.

In the verify read operation associated with the program operation or the erase operation, the pass/fail check block (PFC) 340 may verify the sensing result of the page buffer block 330. For example, in the verify read operation that is performed in the program operation, the pass/fail check block (PFC) 340 may count the number of values (e.g., the number of 0s) corresponding to on-cells that are not programmed to a target threshold voltage or higher.

In the verify read operation that is performed in the erase operation, the pass/fail check block (PFC) 340 may count the number of values (e.g., the number of 1s) corresponding to off-cells that are not erased to a target threshold voltage or lower. When a counting result is greater than or equal to a threshold value, the pass/fail check block (PFC) 340 may output a fail signal to the control logic block 370. When the counting result is smaller than the threshold value, the pass/fail check block (PFC) 340 may output a pass signal to the control logic block 370. Depending on the verification result of the pass/fail check block (PFC) 340, a program loop of the program operation may be further performed, or an erase loop of the erase operation may be further performed.

The data input and output block 350 is connected to the page buffer block 330 through the plurality of data lines DL. The data input and output block 350 may receive a column address CA from the buffer block 360. The data input and output block 350 may output the data read by the page buffer block 330 to the buffer block 360 depending on the column address CA. The data input and output block 350 may provide the data received from the buffer block 360 to the page buffer block 330, based on the column address CA.

Through first signal lines SIGL1, the buffer block 360 may receive a command CMD and an address ADDR from an external device and may exchange data “DATA” with the external device. The buffer block 360 may operate under control of the control logic block 370. The buffer block 360 may provide the command CMD to the control logic block 370. The buffer block 360 may provide the row address RA of the address ADDR to the row decoder block 320 and may provide the column address CA of the address ADDR to the data input and output block 350. The buffer block 360 may exchange the data “DATA” with the data input and output block 350.

The control logic block 370 may exchange a control signal CTRL with the external device through second signal lines SIGL2. The control logic block 370 may allow the buffer block 360 to route the command CMD, the address ADDR, and the data “DATA”. The control logic block 370 may decode the command CMD received from the buffer block 360 and may control the semiconductor device 300 based on the decoded command.

In some embodiments, the semiconductor device 300 may be manufactured in a bonding method. The memory cell array 310 may be manufactured by using a first wafer, and the row decoder block 320, the page buffer block 330, the pass/fail check block (PFC) 340, the data input and output block 350, the buffer block 360, and the control logic block 370 may be manufactured by using a second wafer. The semiconductor device 300 may be implemented by coupling the first wafer and the second wafer such that an upper surface of the first wafer and an upper surface of the second wafer face each other.

As another example, the semiconductor device 300 may be manufactured in a cell over peripheral (COP) method. A peripheral circuit including the row decoder block 320, the page buffer block 330, the pass/fail check block (PFC) 340, the data input and output block 350, the buffer block 360, and the control logic block 370 may be implemented on a substrate. The memory cell array 310 may be implemented over the peripheral circuit. The peripheral circuit and the memory cell array 310 may be connected by using through vias.

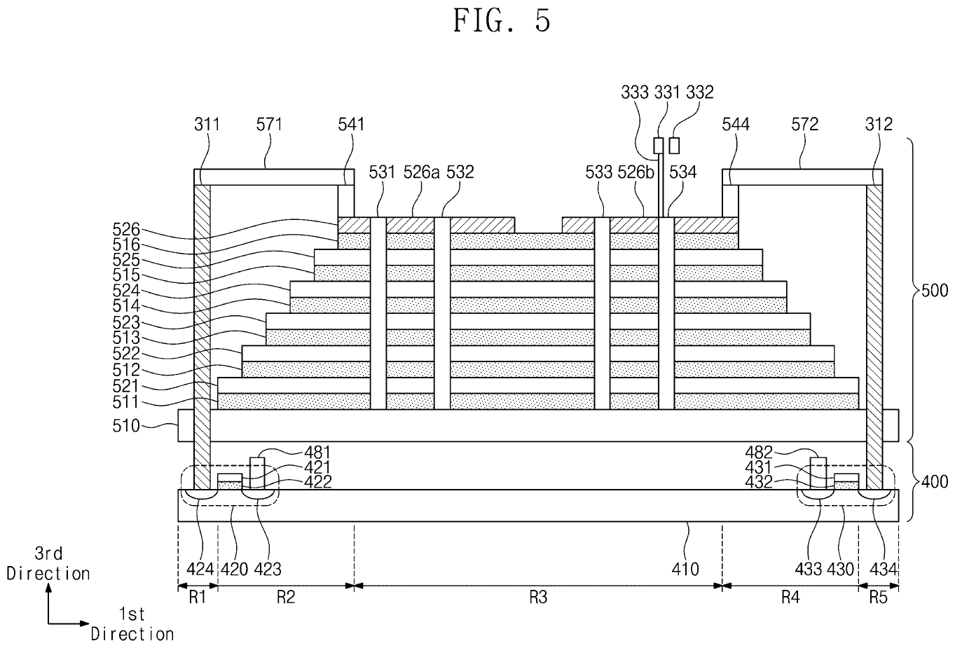

FIG. 5 illustrates an example in which the semiconductor device 300 is manufactured in the COP method. Referring to FIGS. 4 and 5, the semiconductor device 300 may include a peripheral circuit 400 and a cell structure 500 on the peripheral circuit 400. The peripheral circuit 400 may include the row decoder block 320, the page buffer block 330, the pass/fail check block (PFC) 340, the data input and output block 350, the buffer block 360, and the control logic block 370. The cell structure 500 may include the memory cell array 310. For example, the semiconductor device 300 may include the cell over peripheral (COP) structure.

The peripheral circuit 400 may include a first active region 410, and elements 420 and 430 on the first active region 410. The first active region 410 may be formed in a semiconductor substrate. The elements 420 and 430 may include a first pass transistor 420 and a second pass transistor 430.

The first pass transistor 420 may include a gate 421, an insulating layer 422, a first junction 423, and a second junction 424. The second pass transistor 430 may include a gate 431, an insulating layer 432, a first junction 433, and a second junction 434.

The first junction 423 of the first pass transistor 420 may be connected to a first peripheral circuit via 481. The first peripheral circuit via 481 may be connected to a line (or a wire) that is not illustrated. The second junction 424 of the first pass transistor 420 may be connected to a first through via 311. For example, the first through via 311 may be a through hole via (THV).

The first junction 433 of the second pass transistor 430 may be connected to a second peripheral circuit via 482. The second peripheral circuit via 482 may be connected to a line (or a wire) that is not illustrated. The second junction 434 of the second pass transistor 430 may be connected to a second through via 312. For example, the second through via 312 may be a through hole via (THV).

The gate 421 of the first pass transistor 420 and the gate 431 of the second pass transistor 430 may be connected to a common line (e.g., one of lower metal lines of lower metal layers). The first peripheral circuit via 481 and the second peripheral circuit via 482 may be connected to a common line (e.g., one of the lower metal lines of the lower metal layers).

That is, the first pass transistor 420 may operate in response to a common control signal and may transfer a common voltage of the common line to the first through via 311, and the second pass transistor 430 may operate in response to the common control signal and may transfer the common voltage to the second through via 312.

In some embodiments, only the components elements connected to the first through via 311 and the second through via 312 from among the components of the peripheral circuit 400 are illustrated in FIG. 5. Additional components that are not illustrated in FIG. 5 may be added to the peripheral circuit 400.

First to fifth regions R1 to R5 may be divided along a first direction depending on features of components of the cell structure 500. However, the division of the first to fifth regions R1 to R5 is provided for convenience of description, and the present disclosure is not limited thereto.

The cell structure 500 may include a second active region 510 and a vertical structure on the second active region 510. The vertical structure may include a pair of a first insulating layer 511 and a first conductive layer 521, a pair of a second insulating layer 512 and a second conductive layer 522, a pair of a third insulating layer 513 and a third conductive layer 523, a pair of a fourth insulating layer 514 and a fourth conductive layer 524, and a pair of a fifth insulating layer 515 and a fifth conductive layer 525.

A pair of a sixth insulating layer 516 and a sixth conductive layer 526 may be provided on the vertical structure. The sixth conductive layer 526 may include a first partial conductive layer 526a and a second partial conductive layer 526b that are spaced from each other to face each other in the first direction. The first partial conductive layer 526a and the second partial conductive layer 526b may be spaced from each other in the first direction such that the sixth insulating layer 516 under the sixth conductive layer 526 is exposed.

In the third region R3, first to fourth vertical channels 531 to 534 may penetrate (i.e., extend into) the sixth conductive layer 526, the sixth insulating layer 516, and the vertical structure in a third direction.

In some embodiments, an information storage layer including a silicon oxide layer, a silicon nitride layer, and a silicon oxide layer may be formed between the first to sixth conductive layers 521 to 526 and the first to fourth vertical channels 531 to 534.

In the second region R2 and the fourth region R4, the pairs of the first to sixth insulating layers 511 to 516 and the first to sixth conductive layers 521 to 526 may have lengths (e.g., lengths in the first direction) that stepwise decrease along the third direction. For example, the pairs of the first to sixth insulating layers 511 to 516 and the first to sixth conductive layers 521 to 526 together may have a stepped profile.

In the first region R1, the first through via 311 may penetrate (i.e., extend into) the second active region 510 and may extend in the third direction. The first through via 311 may be connected to a first memory cell via 541, which is on a first conductive layer in the first direction from among conductive layers included in the first partial conductive layer 526a, through a first upper conductive layer 571. The first upper conductive layer 571 may be one of upper metals of an upper metal layer.

As in the first through via 311, a through via that is connected to each of the first to fifth conductive layers 521 to 525 through a relevant pass transistor of the peripheral circuit 400, a relevant upper conductive layer, and a relevant partial conductive layer may be provided in the first region R1.

In the fifth region R5, the second through via 312 may penetrate (i.e., extend into) the second active region 510 and may extend in the third direction. The second through via 312 may be connected to a second memory cell via 544 through a second upper conductive layer 572. The second upper conductive layer 572 may be one of the upper metals of the upper metal layer.

As in the second through via 312, a through via that is connected to each of the first to fifth conductive layers 521 to 525 through a relevant pass transistor of the peripheral circuit 400, a relevant upper conductive layer, and a relevant partial conductive layer may be provided in the fifth region R5.

In the third region R3, conductive lines (e.g., some of metal lines of upper metal layers) may be provided on/over the sixth conductive layer 526. To prevent a drawing from being unnecessarily complicated, two conductive lines, that is, first and second conductive lines 331 and 332 are illustrated as an example. The first and second conductive lines 331 and 332 may extend in the second direction. The first conductive line 331 may be connected to the fourth vertical channel 534 through a conductive line via 333.

The first pass transistor 420 and the second pass transistor 430 may be included in the row decoder block 320. The first through via 311 and the second through via 312 may be lines (or wires) connecting the row decoder block 320 and the memory cell array 310.

As described above, the lines that includes the first through via 311 and the second through via 312 and connect the row decoder block 320 and the memory cell array 310 may be provided by using the THVs. In addition, lines connecting the memory cell array 310 and the page buffer block 330 and lines connecting the cell structure 500 and the peripheral circuit 400 may be provided in the first region R1 and the fifth region R5 by using the THVs.

The THVs may be disposed only at limited locations of the first region R1 and the fifth region R5. Because the area of the first region R1 and the fifth region R5 is limited, the number of THVs capable of being disposed in the first region R1 and the fifth region R5 may also be limited. That is, the THVs may be the limited connecting elements.

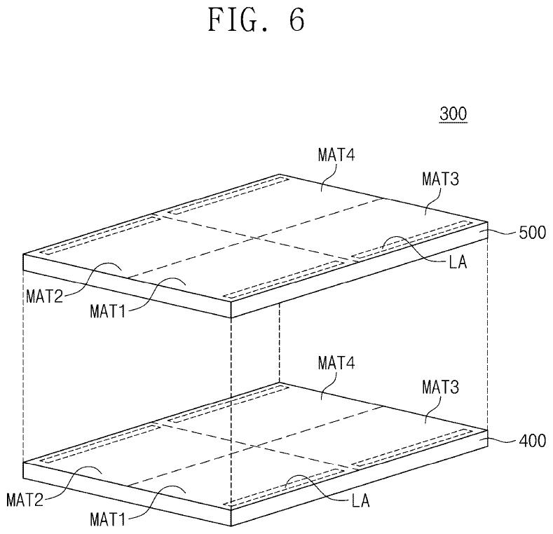

FIG. 6 illustrates an example of mats of the semiconductor device 300. Referring to FIGS. 5 and 6, the peripheral circuit 400 may include a first mat MAT1, a second mat MAT2, a third mat MAT3, and a fourth mat MAT4. The cell structure 500 may also include a first mat MAT1, a second mat MAT2, a third mat MAT3, and a fourth mat MAT4.

The THVs may be provided in limited areas LA (also referred to as limited locations) of the first mat MAT1, the second mat MAT2, the third mat MAT3, and the fourth mat MAT4 of each of the peripheral circuit 400 and the cell structure 500. When the circuit schematics for manufacturing the peripheral circuit 400 are completed, the electronic device 100 may partition the circuit components of the circuit schematics into the first mat MAT1, the second mat MAT2, the third mat MAT3, and the fourth mat MAT4.

The number of THVs necessary in each mat may vary depending on whether to partition any circuit components among the circuit components of the circuit schematics into any mat. For example, interconnections between the peripheral circuit 400 and the cell structure 500 may cause the increase in the number of THVs necessary in the corresponding mat(s).

For example, interconnections between circuit components belonging to the same mat may be implemented by using metal lines of lower metal layers of the peripheral circuit 400. However, interconnections between circuit components belonging to different mats should be implemented by using the THVs and metal lines of upper metal layers of the cell structure 500. That is, interconnections between circuit components belonging to different mats may cause the increase in the number of THVs necessary in mats.

For example, as the number of THVs necessary for a circuit component partitioned into a specific mat increase, the number of THVs necessary in the specific mat may increase. When the number of THVs necessary in the specific mat is more than the number of THVs capable of being provided in the limited area LA of the specific mat, a result of the above partitioning is incapable of being used to manufacture the semiconductor device 300.

The electronic device 100 according to some embodiments of the present disclosure calculates the PnR availability in advance based on the limited connecting elements and generates the layout image LO by performing the PnR when the PnR availability indicates that the PnR is available. Accordingly, it is possible to prevent an unavailable layout image LO from being generated, and it is possible to prevent a time taken to manufacture the semiconductor device 300 from being wasted.

FIG. 6 illustrates that the semiconductor device 300 includes the first mat MAT1, the second mat MAT2, the third mat MAT3, and the fourth mat MAT4 for each of the peripheral circuit 400 and the cell structure 500. However, the present disclosure is not limited to embodiments in which the semiconductor device 300 includes the first mat MAT1, the second mat MAT2, the third mat MAT3, and the fourth mat MAT4 for each of the peripheral circuit 400 and the cell structure 500. For example, when the entire layout of the semiconductor device 300 is changed, the number of mats may also be changed, and locations, sizes, and the number of limited areas LA may also be changed.

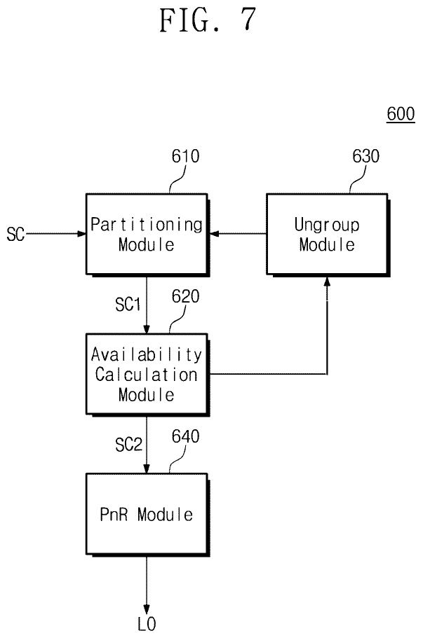

FIG. 7 illustrates an example of a layout generation module 600. In some embodiments, the layout generation module 600 may correspond to the layout generation module 11 of FIG. 1. Referring to FIGS. 1 and 7, the layout generation module 600 may include a partitioning module 610, an availability calculation module 620, an ungroup module 630, and a PnR module 640.

The partitioning module 610 may receive circuit schematics SC from the database 15. The circuit schematics SC may include circuit components for manufacturing the semiconductor device 300. The partitioning module 610 may partition the circuit components of the circuit schematics SC into the first mat

MAT1, the second mat MAT2, the third mat MAT3, and the fourth mat MAT4. Alternatively, some circuit components of the circuit schematics SC may be ungrouped by the ungroup module 630. The partitioning module 610 may partition the circuit components of the circuit schematics SC including the ungrouped circuit components into the first mat MAT1, the second mat MAT2, the third mat MAT3, and the fourth mat MAT4.

For example, the partitioning module 610 may partition circuit components of a current level into the first mat MAT1, the second mat MAT2, the third mat MAT3, and the fourth mat MAT4. The partitioning module 610 may partition the circuit components into the first mat MAT1, the second mat MAT2, the third mat MAT3, and the fourth mat MAT4 and may generate first circuit schematics SC1.

The availability calculation module 620 may receive the first circuit schematics SC1 from the partitioning module 610. The first circuit schematics SC1 may include the circuit components partitioned into the first mat MAT1, the second mat MAT2, the third mat MAT3, and the fourth mat MAT4. The availability calculation module 620 may calculate the availability of the partitioned circuit components for each of the first mat MAT1, the second mat MAT2, the third mat MAT3, and the fourth mat MAT4. The availability calculation module 620 may calculate whether the circuit components partitioned into each of the first mat MAT1, the second mat MAT2, the third mat MAT3, and the fourth mat MAT4 satisfy the limits (e.g., the number of THVs and the entire area) applied to the process of manufacturing the semiconductor device 300.

When the calculated availability indicates that the PnR is available, the availability calculation module 620 may output the first circuit schematics SC1 being available, as second circuit schematics SC2. When the calculated availability indicates that the PnR is unavailable, the availability calculation module 620 may notify the ungroup module 630 that the first circuit schematics SC1 are unavailable.

When the first circuit schematics SC1 are unavailable, the ungroup module 630 may select one of the circuit components of the current level of the first circuit schematics SC1. The ungroup module 630 may ungroup the selected circuit component and may call circuit components of an immediately underlying level of the selected circuit component to the current level. Afterwards, the partitioning module 610 may partition the circuit components of the current level to generate the first circuit schematics SC1, and the availability calculation module 620 may again calculate the availability of the first circuit schematics SC1.

When the first circuit schematics SC1 are available, the PnR module 640 may receive the second circuit schematics SC2 from the availability calculation module 620. The PnR module 640 may generate the layout image LO by performing the PnR based on the second circuit schematics SC2. The layout image LO may be output to the modification module 12.

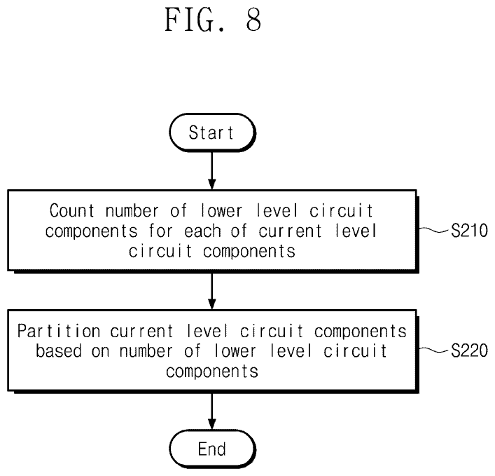

FIG. 8 illustrates an example of a method in which the partitioning module 610 partitions circuit components. Referring to FIGS. 7 and 8, in operation S210, the partitioning module 610 may count the number of lower-level circuit components for each of current-level circuit components. For example, the partitioning module 610 may count the number of lower-level circuit components of an immediately underlying level of a current-level circuit component or the number of lower-level circuit components of two or more lower levels, which are included in the current-level circuit component.

In operation S220, the partitioning module 610 may partition the current-level circuit components, based on the number of lower-level circuit components. For example, the partitioning module 610 may partition the current-level circuit components into the first mat MAT1, the second mat MAT2, the third mat MAT3, and the fourth mat MAT4 such that the numbers of circuit components included in the first mat MAT1, the second mat MAT2, the third mat MAT3, and the fourth mat MAT4 (e.g., counts of lower-level circuit components) approximate. As used herein, “approximate” means close to the same but not necessarily the same. For example, the partitioning module 610 may partition the current-level circuit components into the first mat MAT1, the second mat MAT2, the third mat MAT3, and the fourth mat MAT4 such that a sum of counts of lower-level circuit components included in the first mat MAT1, a sum of counts of lower-level circuit components included in the second mat MAT2, a sum of counts of lower-level circuit components included in the third mat MAT3, and a sum of counts of lower-level circuit components included in the fourth mat MAT4 are close to the same but not necessarily the same. In some embodiments, the sum of counts of lower-level circuit components included in the first mat MAT1, the sum of counts of lower-level circuit components included in the second mat MAT2, the sum of counts of lower-level circuit components included in the third mat MAT3, and the sum of counts of lower-level circuit components included in the fourth mat MAT4 may each be within 10 (e.g., 10 counts) of each other.

For example, the partitioning module 610 may sequentially select circuit components, which are not yet partitioned, from a circuit component with the highest count in order from greatest to smallest and may partition the circuit components into the first mat MAT1, the second mat MAT2, the third mat MAT3, and the fourth mat MAT4. Afterwards, the partitioning module 610 may sequentially select current-level circuit components, which are not yet partitioned, from a circuit component with the highest count in order from greatest to smallest and may partition the circuit components into the fourth mat MAT4, the third mat MAT3, the second mat MAT2, and the first mat MAT1 (e.g., in a counterclockwise (or reverse) order). In some embodiments, when circuit components having the same count exist, the partitioning module 610 may first select a circuit component with a larger area or a circuit component with a smaller area.

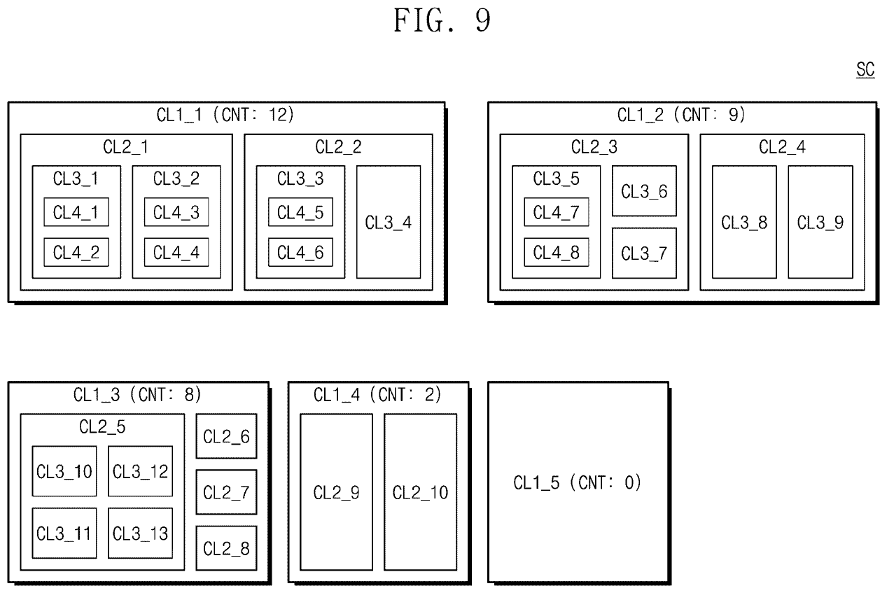

FIG. 9 illustrates an example of circuit components of circuit schematics SC. Referring to FIG. 9, the circuit schematics SC may include a first circuit component CL1_1, a second circuit component CL1_2, a third circuit component CL1_3, a fourth circuit component CL1_4, and a fifth circuit component CL1_5, which belong to a first level.

The first circuit component CL1_1 of the first level may include a first circuit component CL2_1 and a second circuit component CL2_2, which belong to a second level, as lower circuit components. The first circuit component CL2_1 of the second level may include a first circuit component CL3_1 and a second circuit component CL3_2, which belong to a third level. The first circuit component CL3_1 of the third level may include a first circuit component CLA_1 and a second circuit component CL4_2, which belong to a fourth level. The second circuit component CL3_2 of the third level may include a third circuit component CL4_3 and a fourth circuit component CL4_4, which belong to the fourth level. The second circuit component CL2_2 of the second level may include a third circuit component CL3_3 and a fourth circuit component CL3_4, which belong to the third level. The third circuit component CL3_3 of the third level may include a fifth circuit component CL4_5 and a sixth circuit component CL4_6, which belong to the fourth level.

In some embodiments, a count CNT of the first circuit component CL1_1 of the first level may be the number of circuit components of lower levels (e.g., the number of circuit components of all lower levels) of the first circuit component CL1_1 of the first level. The count CNT of the first circuit component CL1_1 of the first level may be 12. As another example, in the case of counting the number of circuit components of an immediately underlying level, the count CNT of the first circuit component CL1_1 of the first level may be 2. For example, the immediately underlying level may include the first circuit component CL2_1 and the second circuit component CL2_2 of the second level.

The second circuit component CL1_2 of the first level may include a third circuit component CL2_3 and a fourth circuit component CL2_4, which belong to the second level, as lower circuit components. The third circuit component CL2_3 of the second level may include a fifth circuit component CL3_5, a sixth circuit component CL3_6, and a seventh circuit component CL3_7, which belong to the third level. The fifth circuit component CL3_5 of the third level may include a seventh circuit component CL4_7 and an eighth circuit component CLA_8, which belong to the fourth level. The fourth circuit component CL2_4 of the second level may include an eighth circuit component CL3_8 and a ninth circuit component CL3_9, which belong to the third level.

In some embodiments, a count CNT of the second circuit component CL1_2 of the first level may be the number of circuit components of lower levels (e.g., the number of circuit components of all lower levels) of the second circuit component CL1_2 of the first level. The count CNT of the second circuit component CL1_2 of the first level may be 9. As another example, in the case of counting the number of circuit components of an immediately underlying level, the count CNT of the second circuit component CL1_2 of the first level may be 2. For example, the immediately underlying level may include the third circuit component CL2_3 and the fourth circuit component CL2_4 of the second level.

The third circuit component CL1_3 of the first level may include a fifth circuit component CL2_5, a sixth circuit component CL2_6, a seventh circuit component CL2_7, and an eighth circuit component CL2_8, which belong to the second level, as lower circuit components. The fifth circuit component CL2_5 of the second level may include a tenth circuit component CL3_10, an eleventh circuit component CL3_11, a twelfth circuit component CL3_12, and a thirteenth circuit component CL3_13, which belong to the third level.

In some embodiments, a count CNT of the third circuit component CL1_3 of the first level may be the number of circuit components of lower levels (e.g., the number of circuit components of all lower levels) of the third circuit component CL1_3 of the first level. The count CNT of the third circuit component CL1_3 of the first level may be 8. As another example, in the case of counting the number of circuit components of an immediately underlying level, the count CNT of the third circuit component CL1_3 of the first level may be 4. For example, the immediately underlying level may include the fifth circuit component CL2_5, the sixth circuit component CL2_6, the seventh circuit component CL2_7, and the eighth circuit component CL2_8 of the second level.

The fourth circuit component CL1_4 of the first level may include a ninth circuit component CL2_9 and a tenth circuit component CL2_10, which belong to the second level, as lower circuit components. In some embodiments, a count CNT of the fourth circuit component CL1_4 of the first level may be the number of circuit components of lower levels (e.g., the number of circuit components of all lower levels) of the fourth circuit component CL1_4 of the first level. The count CNT of the fourth circuit component CL1_4 of the first level may be 2. As another example, in the case of counting the number of circuit components of an immediately underlying level, the count CNT of the fourth circuit component CL1_4 of the first level may be 2. For example, the immediately underlying level may be the only lower level and may include the ninth circuit component CL2_9 and the tenth circuit component CL2_10 of the second level.

The fifth circuit component CL1_5 of the first level may not include a lower circuit component. In some embodiments, a count CNT of the fifth circuit component CL1_5 of the first level may be the number of circuit components of lower levels (e.g., the number of circuit components of all lower levels) of the fifth circuit component CL1_5 of the first level. The count CNT of the fifth circuit component CL1_5 of the first level may be 0.

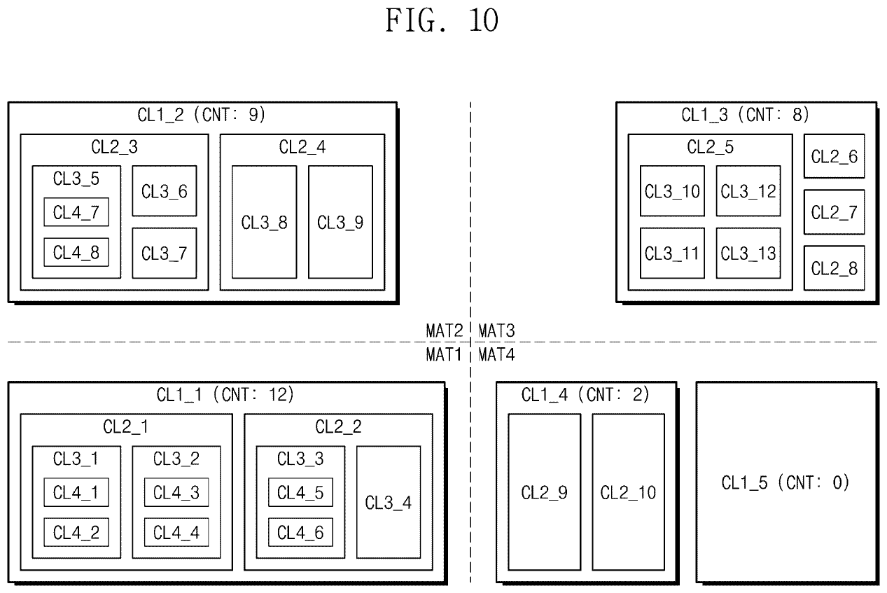

FIG. 10 illustrates an example in which the partitioning module 610 partitions the circuit schematics SC of FIG. 9 to generate a first circuit schematics SC1. Referring to FIGS. 7 and 10, the partitioning module 610 may partition circuit components of a current level, for example, the first circuit component CL1_1, the second circuit component CL1_2, the third circuit component CL1_3, the fourth circuit component CL1_4, and the fifth circuit component CL1_5, which belong to the first level, into the first mat MAT1, the second mat MAT2, the third mat MAT3, and the fourth mat MAT4.

For example, the partitioning module 610 may partition the circuit components of the current level such that counts of circuit components partitioned into the first mat MAT1, the second mat MAT2, the third mat MAT3, and the fourth mat MAT4 approximate.

For example, based on a clockwise order, the partitioning module 610 may allocate the first circuit component CL1_1 of the first level, which has the highest count CNT of 12, to the first mat MAT1, may allocate the second circuit component CL1_2 of the first level, which has the second highest count CNT of 9, to the second mat MAT2, may allocate the third circuit component CL1_3 of the first level, which has the third highest count CNT of 8, to the third mat MAT3, and may allocate the fourth circuit component CL1_4 of the first level, which has the fourth highest count CNT of 2, to the fourth mat MAT4. Afterwards, for example, based on a counterclockwise order, the partitioning module 610 may allocate the fifth circuit component CL1_5 of the first level, which has the fifth highest count CNT of 0, to the fourth mat MAT4.

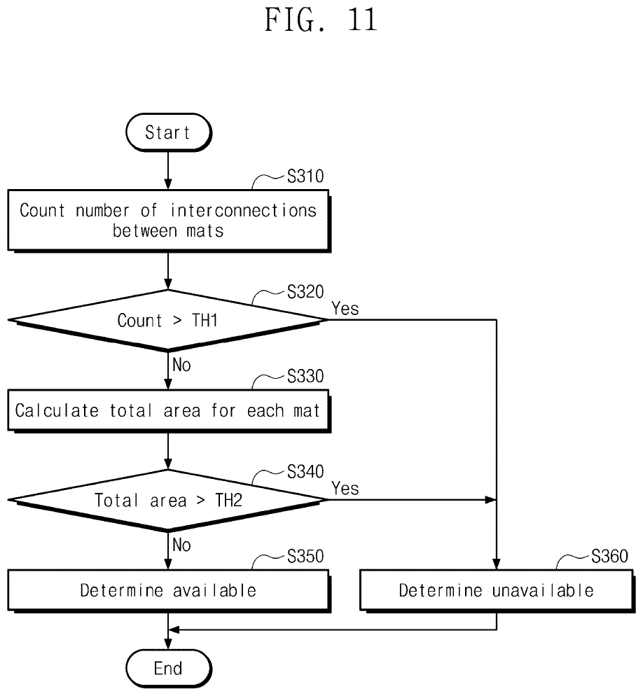

FIG. 11 illustrates an example of a method in which the availability calculation module 620 calculates the availability of the first circuit schematics SC1. Referring to FIGS. 5, 7, and 11, in operation S310, the availability calculation module 620 may count interconnections between mats. For example, the number and locations of THVs corresponding to interconnections between the peripheral circuit 400 and the cell structure 500 may be determined depending on a structure of the cell structure 500.

The number of THVs required for each mat may vary depending on the numbers and kinds of circuit components partitioned into the first mat MAT1, the second mat MAT2, the third mat MAT3, and the fourth mat MAT4. The availability calculation module 620 may count the number of THVs changed due to the partitioning of circuit components by counting interconnections between mats.

In operation S320, the availability calculation module 620 may determine whether the count (or a result of the counting in operation S310) is greater than a first threshold value TH1. For example, the first threshold value TH1 may be the remainder other than the number (or the area) used by THVs corresponding to interconnections between the peripheral circuit 400 and the cell structure 500 in the limited areas LA (refer to FIG. 6). For example, the first threshold value TH1 may be a budget capable of being used for THVs associated with the connection between circuit components of the peripheral circuit 400 in the limited areas LA. That is, the first threshold value TH1 may be a number of limited connecting elements (e.g., THVs) allowed in each mat.

When the count is greater than the first threshold value TH1 (e.g., Yes in operation S320), in operation S360, the availability calculation module 620 may determine that the PnR is unavailable. When the count is not greater than the first threshold value TH1 or is smaller than or equal to the first threshold value TH1 (e.g., No in operation S320), in operation S330, the availability calculation module 620 may calculate the total area for each mat. For example, the availability calculation module 620 may calculate the total area of circuit components included in each mat.

In operation S340, the availability calculation module 620 may determine whether the total area is greater than a second threshold value TH2. For example, the second threshold value TH2 may indicate the area allowed for each mat. When the total area is greater than the second threshold value TH2 (e.g., Yes in operation S340), in operation S360, the availability calculation module 620 may determine that the first circuit schematics SC1 is unavailable. When the total area is not greater than the second threshold value TH2 or is smaller than or equal to the second threshold value TH2 (e.g., No in operation S340), in operation S350, the availability calculation module 620 may determine that the first circuit schematics SC1 is available.

As described above, when at least the THV requirement is satisfied (e.g., when it is determined in operation S320 that the count is not greater than the first threshold value TH1) and when the area requirement is satisfied (e.g., when it is determined in operation S340 that the total area is not greater than the second threshold value TH2), the availability calculation module 620 may determine that the first circuit schematics SC1 is available. When at least one of the THV requirement or the area requirement is not satisfied, the availability calculation module 620 may determine that the first circuit schematics SC1 is unavailable.

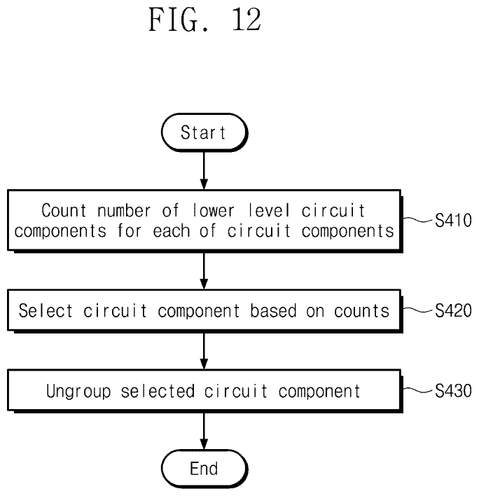

FIG. 12 illustrates an example of a method in which the ungroup module 630 ungroups a circuit component of a current level. Referring to FIGS. 7 and 12, in operation S410, the ungroup module 630 may count the number of lower-level circuit components for each of current-level circuit components. Operation S410 may be the same as operation S210 of FIG. 8. In some embodiments, when counts of circuit components of a current level generated by the partitioning module 610 in operation S210 of FIG. 8 exist, the ungroup module 630 may not perform operation S410 and may receive the counts of the circuit components of the current level from the partitioning module 610.

In operation S420, the ungroup module 630 may select a circuit component based on the counts. For example, the ungroup module 630 may select a circuit component having the highest count from among the circuit components of the current level. When counts of two or more circuit components of the current level are equal, the ungroup module 630 may select a circuit component having a larger area or a circuit component having a smaller area from among the two or more circuit components.

In some embodiments, when the total area exceeds the second threshold value TH2, that is, when the availability is determined to be unavailable, the ungroup module 630 may select a circuit component of the current level preferentially in consideration of the area. For example, the ungroup module 630 may select a circuit component of the current level, which includes circuit components of a lower level and has the larger area. When two or more circuit components including circuit components of a lower level have the same area, the ungroup module 630 may select a circuit component having a higher count or a circuit component having a smaller count.

In operation S430, the ungroup module 630 may ungroup the selected circuit component. For example, the ungroup module 630 may remove the selected circuit component from the current level and may add circuit components of an immediately underlying level of the selected circuit component as circuit components of the current level.

In some embodiments, instead of performing operation S410 and operation S420, the ungroup module 630 may allow the user to select one of the circuit components of the current level. For example, the ungroup module 630 may output a message to the user through the display 161 (refer to FIG. 2) and may receive selection information from the user through a user input interface such as the mouse 163, the keyboard 164, or the touch input device 165. The ungroup module 630 may ungroup a circuit component of the current level, which corresponds to the selection information.

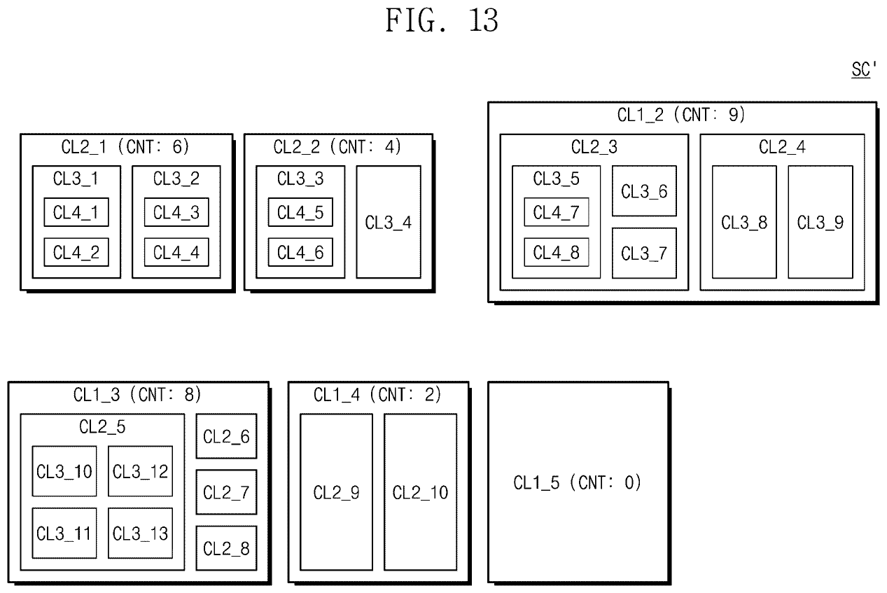

FIG. 13 illustrates an example in which the ungroup module 630 ungroups a circuit component. In some embodiments, the ungroup module 630 may ungroup the first circuit component CL1_1 of the first level having the highest count CNT of 12 from among the first circuit component CL1_1, the second circuit component CL1_2, the third circuit component CL1_3, the fourth circuit component CL1_4, and the fifth circuit component CL1_5, which belong to the first level being the current level of FIG. 9. The ungroup module 630 may call the first circuit component CL2_1 and the second circuit component CL2_2 of the second level being an immediately underlying level of the first circuit component CL1_1 of the first level to the current level. Through the ungrouping, the ungroup module 630 may generate circuit schematics SC′ having circuit components of the current level, which include the first circuit component CL2_1 and the second circuit component CL2_2 of the second level and the second circuit component CL1_2, the third circuit component CL1_3, the fourth circuit component CL1_4, and the fifth circuit component CL1_5 of the first level.

In some embodiments, in the case of performing ungrouping based on counts of circuit components of an immediately underlying level, which are included in the circuit component of the current level, the ungroup module 630 may ungroup the third circuit component CL1_3 of the first level.

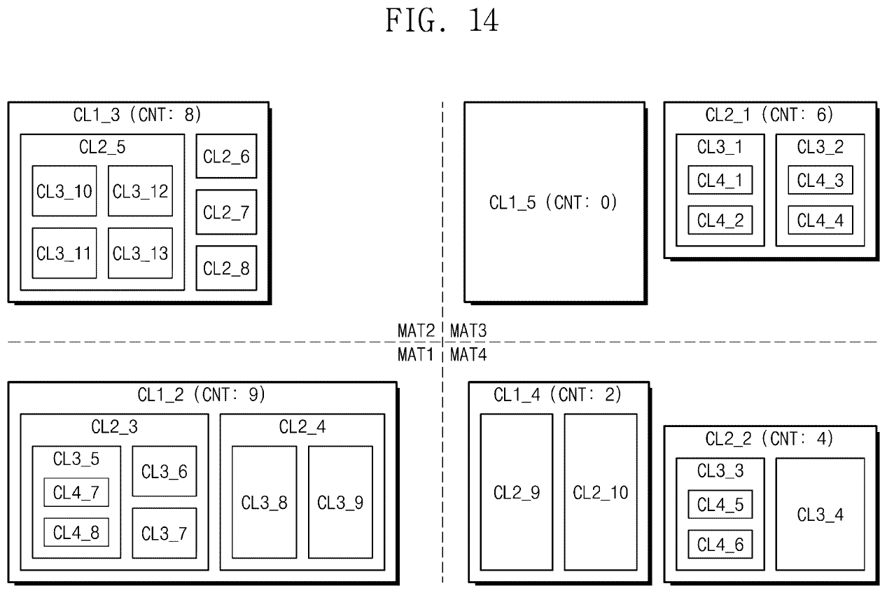

FIG. 14 illustrates an example in which the partitioning module 610 partitions the circuit schematics SC′ of FIG. 13 to generate the first circuit schematics SC1. Referring to FIGS. 7 and 14, the partitioning module 610 may partition circuit components of a current level, for example, the first circuit component CL2_1 and the second circuit component CL2_2 of the second level and the second circuit component CL1_2, the third circuit component CL1_3, the fourth circuit component CL1_4, and the fifth circuit component CL1_5 of the first level into the first mat MAT1, the second mat MAT2, the third mat MAT3, and the fourth mat MAT4.

For example, the partitioning module 610 may partition the circuit components of the current level such that counts of circuit components partitioned into the first mat MAT1, the second mat MAT2, the third mat MAT3, and the fourth mat MAT4 approximate.

For example, based on a clockwise order, the partitioning module 610 may allocate the second circuit component CL1_2 of the first level, which has the highest count CNT of 9, to the first mat MAT1, may allocate the third circuit component CL1_3 of the first level, which has the second highest count CNT of 8, to the second mat MAT2, may allocate the first circuit component CL2_1 of the second level, which has the third highest count CNT of 6, to the third mat MAT3, and may allocate the second circuit component CL2_2 of the second level, which has the fourth highest count CNT of 4, to the fourth mat MAT4. Afterwards, for example, based on a counterclockwise order, the partitioning module 610 may allocate the fourth circuit component CL1_4 of the first level, which has the fifth highest count CNT of 2, to the fourth mat MAT4 and may allocate the fifth circuit component CL1_5 of the first level, which has the sixth highest count CNT of 0, to the third mat MAT3.

As described above, when the availability of the first circuit schematics SC1 indicates that the PnR is unavailable, the layout generation module 11 (refer to FIG. 1) may increase the number of circuit components of a current level, which are partitioned into mats, by ungrouping a circuit component of the current level. Accordingly, when the THV requirements and the area requirements of circuit components are distributed to mats, and thus, the availability may be prevented from being not satisfied due to the concentration of the THV requirement or the area requirement on any one mat.

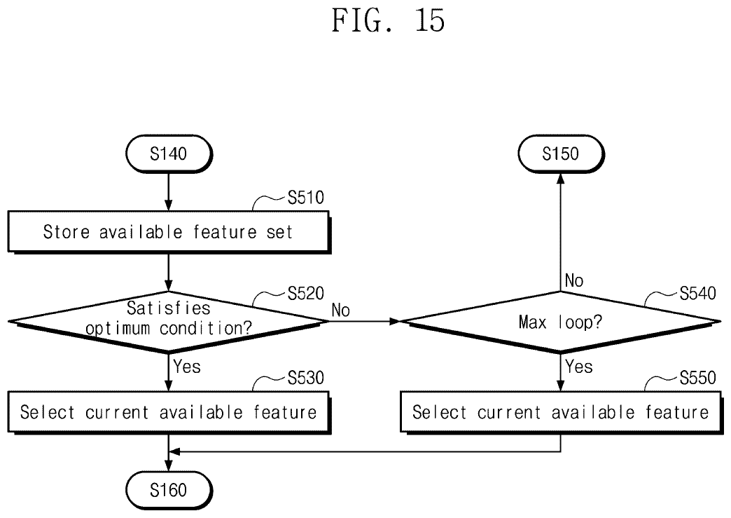

FIG. 15 illustrates an example of a method in which the layout generation module 11 optimizes the layout image LO. Referring to FIGS. 1, 3, and 15, operation S510 may be performed following operation S140. In operation S510, the layout generation module 11 may store an available feature set. The available feature set may include the first circuit schematics SC1 being available, the maximum THV utilization rate among available THV utilization rates of mats of the first circuit schematics SC1 being available (e.g., the ratio of the number of THVs of circuit components partitioned into each mat to the number of THVs allowed for each mat), and the maximum area utilization rate among available area utilization rates of the first circuit schematics SC1 being available (e.g., the ratio of the total area of circuit components partitioned to each mat to the area allowed for each mat).

For example, the layout generation module 11 may store the available feature set in the random access memory 120, the storage device 140, or the database 15 of the electronic device 100 (refer to FIG. 2).

In operation S520, the layout generation module 11 may determine whether the stored feature set satisfies an optimum condition. For example, the optimum condition may be defined as the THV utilization rate or the area utilization rate. When the THV utilization rate is smaller than or equal to a third threshold value or when the area utilization rate is smaller than or equal to a fourth threshold value, the layout generation module 11 may determine that the optimum condition is satisfied.

When the optimum condition is satisfied (e.g., Yes in operation S520), in operation S530, the layout generation module 11 may select a current available feature set. For example, the layout generation module 11 may select the first circuit schematics SC1 of the current available feature set. Afterwards, the layout generation module 11 may perform operation S160.

When the optimum condition is not satisfied (e.g., No in operation S520), in operation S540, the layout generation module 11 may determine whether a current loop reaches a maximum loop. For example, when the available feature set is stored as much as the number of times corresponding to a fifth threshold value, the layout generation module 11 may determine whether the current loop reaches the maximum loop.

When the current loop does not reach the maximum loop (e.g., No in operation S540), the layout generation module 11 may again perform operation S150. When the current loop reaches the maximum loop (e.g., Yes in operation S540), in operation S550, the layout generation module 11 may select an optimum available feature set. For example, the layout generation module 11 may select the first circuit schematics SC1 of an available feature set having the lowest THV utilization rate or the lowest area utilization rate from among the stored feature sets. Afterwards, the layout generation module 11 may perform operation S160.

In some embodiments, when an available feature set not satisfying the optimum condition is stored and the current loop does not reach the maximum loop (e.g., No in operation S520 and No in operation S540), the layout generation module 11 may perform operation S120 instead of operation S150. For example, the layout generation module 11 may omit ungrouping and may partition circuit components into mats in operation S120. For example, the layout generation module 11 may change the order of partitioning circuit components and may partition circuit components into mats by using the changed partitioning order.

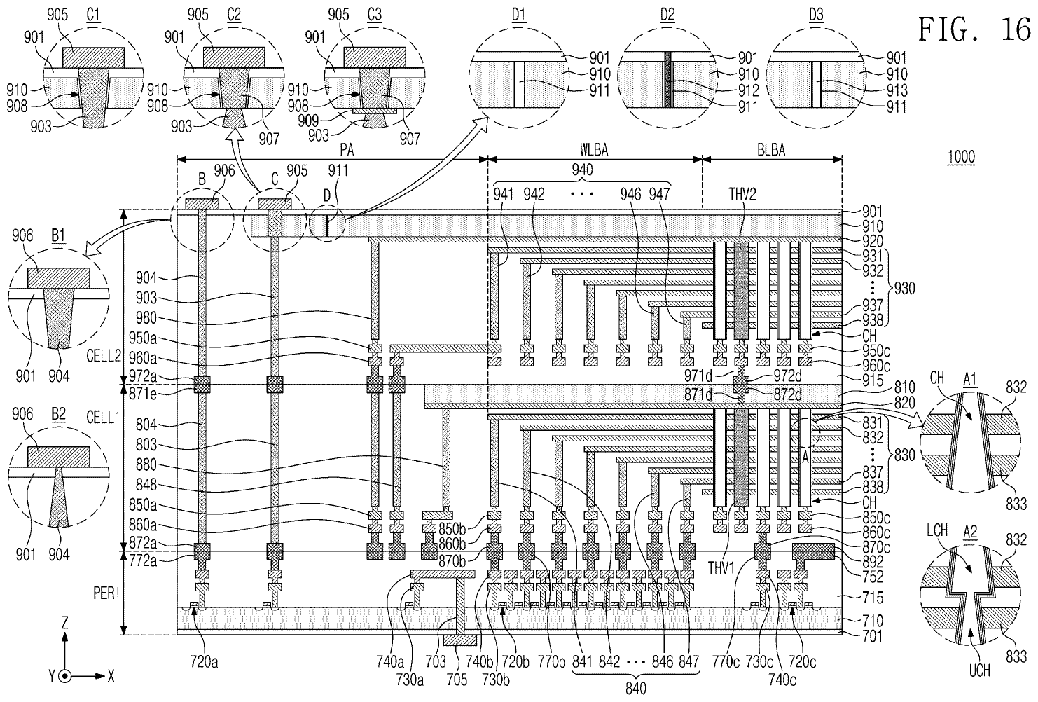

FIG. 16 is a view for describing a semiconductor device 1000 according to some embodiments of the present disclosure. For example, the semiconductor device 1000 may include a volatile memory device such as a dynamic random access memory or a static random access memory or a nonvolatile memory device such as a NAND flash memory, a NOR flash memory, a phase-change memory, a ferroelectric memory, a magnetic memory, or a resistive memory.

Referring to FIG. 16, the semiconductor device 1000 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

The semiconductor device 1000 may include at least one upper chip including a cell region. For example, as illustrated in FIG. 16, the semiconductor device 1000 may be implemented to include two upper chips. However, this is illustrative, and the number of upper chips is not limited thereto. In the case in which the semiconductor device 1000 is implemented to include two upper chips, the semiconductor device 1000 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 16, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the semiconductor device 1000 may include an external pad bonding region PA, a word line bonding region WLBA, and a bit line bonding region BLBA.

The peripheral circuit region PERI may include a first substrate 710 and a plurality of circuit elements 720a, 720b, and 720c formed on the first substrate 710. An interlayer insulating layer 715 including one or more insulating layers may be provided on the plurality of circuit elements 720a, 720b, and 720c, and a plurality of metal lines connecting the plurality of circuit elements 720a, 720b, and 720c may be provided in the interlayer insulating layer 715. For example, the plurality of metal lines may include first metal lines 730a, 730b, and 730c connected with the plurality of circuit elements 720a, 720b, and 720c, respectively, and second metal lines 740a, 740b, and 740c formed on the first metal lines 730a, 730b, and 730c, respectively. The plurality of metal lines may be formed of at least one of various conductive materials. For example, the first metal lines 730a, 730b, and 730c may be formed of tungsten having a relatively high electrical resistivity, and the second metal lines 740a, 740b, and 740c may be formed of copper having a relatively low electrical resistivity.

In this specification, only the first metal lines 730a, 730b, and 730c and the second metal lines 740a, 740b, and 740c are illustrated and described. However, without being limited thereto, one or more additional metal lines may be further formed on the second metal lines 740a, 740b, and 740c. In this case, the second metal lines 740a, 740b, and 740c may be formed of aluminum. At least some of the additional metal lines formed on the second metal lines 740a, 740b, and 740c may be formed of copper having a lower electrical resistivity than the aluminum of the second metal lines 740a, 740b, and 740c.

The interlayer insulating layer 715 may be disposed on the first substrate 710 and may include an insulating material, such as silicon oxide or silicon nitride.

Each of the first and second cell regions CELL1 and CELL2 may include at least one memory block. The first cell region CELL1 may include a second substrate 810 and a common source line 820. A plurality of word lines 830 (831 to 838) may be stacked on the second substrate 810 in a direction (the Z-axis direction) perpendicular to an upper surface of the second substrate 810. String selection lines and a ground selection line may be disposed on and under the word lines 830, and the plurality of word lines 830 may be disposed between the string selection lines and the ground selection line. Likewise, the second cell region CELL2 may include a third substrate 910 and a common source line 920, and a plurality of word lines 930 (931 to 938) may be stacked in a direction (the Z-axis direction) perpendicular to an upper surface of the third substrate 910. The second substrate 810 and the third substrate 910 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In some embodiments, as illustrated in A1, the channel structure CH may be provided in the bit line bonding region BLBA and may extend in the direction perpendicular to the upper surface of the second substrate 810 to penetrate (i.e., extend into) the word lines 830, the string selection lines, and the ground selection line. The channel structure CH may include a data storage layer, a channel layer, and a buried insulating layer. The channel layer may be electrically connected with a first metal line 850c and a second metal line 860c in the bit line bonding region BLBA. For example, the second metal line 860c may be a bit line and may be connected to the channel structure CH through the first metal line 850c. The bit line 860c may extend in a first direction (a Y-axis direction) parallel to the upper surface of the second substrate 810.

In some embodiments, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 810 and may penetrate (i.e., extend into) the common source line 820 and the lower word lines 831 and 832. The lower channel LCH may include a data storage layer, a channel layer, and a buried insulating layer and may be connected with the upper channel UCH. The upper channel UCH may penetrate (i.e., extend into) the upper word lines 833 to 838. The upper channel UCH may include a data storage layer, a channel layer, and a buried insulating layer, and the channel layer of the upper channel UCH may be electrically connected with the first metal line 850c and the second metal line 860c. As the length of a channel is increased, it may be difficult to form a channel having a constant width due to process reasons. The semiconductor device 1000 according to some embodiments of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 832 and the word line 833 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 831 and 832 penetrated by the lower channel LCH is smaller than the number of upper word lines 833 to 838 penetrated by the upper channel UCH. However, this is illustrative, and the present disclosure is not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 16, the first through-electrode THV1 may penetrate (i.e., extend into) the common source line 820 and the plurality of word lines 830. However, this is illustrative, and the first through-electrode THV1 may additionally penetrate the second substrate 810. The first through-electrode THV1 may include a conductive material. In some embodiments, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected through a first through-metal pattern 872d and a second through-metal pattern 972d. The first through-metal pattern 872d may be formed on a lower side of the first upper chip including the first cell region CELL1, and the second through-metal pattern 972d may be formed on an upper side of the second upper chip including the second cell region CELL2. The first through-electrode THV1 may be electrically connected with the first metal line 850c and the second metal line 860c. A lower VIA 871d may be formed between the first through-electrode THV1 and the first through-metal pattern 872d, and an upper VIA 971d may be formed between the second through-electrode THV2 and the second through-metal pattern 972d. The first through-metal pattern 872d and the second through-metal pattern 972d may be connected by a bonding method.

Furthermore, in the bit line bonding region BLBA, an upper metal pattern 752 may be formed on the uppermost metal layer of the peripheral circuit region PERI, and an upper metal pattern 892 having the same shape as the upper metal pattern 752 may be formed on the uppermost metal layer of the first cell region CELL1. The upper metal pattern 892 of the first cell region CELL1 and the upper metal pattern 752 of the peripheral circuit region PERI may be electrically connected to each other by a bonding method. In the bit line bonding region BLBA, the bit line 860c may be electrically connected with a page buffer included in the peripheral circuit region PERI. For example, some of the circuit elements 720c of the peripheral circuit region PERI may provide a page buffer, and the bit line 860c may be electrically connected with the circuit elements 720c providing the page buffer through an upper bonding metal 870c of the first cell region CELL1 and an upper bonding metal 770c of the peripheral circuit region PERI.

Continuing to refer to FIG. 16, in the word line bonding region WLBA, the word lines 830 of the first cell region CELL1 may extend in a second direction (an X-axis direction) parallel to the upper surface of the second substrate 810 and may be connected with a plurality of cell contact plugs 840 (841 to 847). A first metal line 850b and a second metal line 860b may be sequentially connected to upper portions of the cell contact plugs 840 connected to the word lines 830. In the word line bonding region WLBA, the cell contact plugs 840 may be connected with the peripheral circuit region PERI through an upper bonding metal 870b of the first cell region CELL1 and an upper bonding metal 770b of the peripheral circuit region PERI.

The cell contact plugs 840 may be electrically connected with a row decoder included in the peripheral circuit region PERI. For example, some of the circuit elements 720b of the peripheral circuit region PERI may provide a row decoder, and the cell contact plugs 840 may be electrically connected with the circuit elements 720b providing the row decoder through the upper bonding metal 870b of the first cell region CELL1 and the upper bonding metal 770b of the peripheral circuit region PERI. In some embodiments, an operating voltage of the circuit elements 720b that provide the row decoder may differ from an operating voltage of the circuit elements 720c that provide the page buffer. For example, the operating voltage of the circuit elements 720c that provide the page buffer may be greater than the operating voltage of the circuit elements 720b that provide the row decoder.

Likewise, in the word line bonding region WLBA, the word lines 930 of the second cell region CELL2 may extend in the second direction (the X-axis direction) parallel to the upper surface of the third substrate 910 and may be connected with a plurality of cell contact plugs 940 (941 to 947). The cell contact plugs 940 may be connected with the peripheral circuit region PERI through an upper metal pattern of the second cell region CELL2, a lower metal pattern and an upper metal pattern of the first cell region CELL1, and a cell contact plug 848.

In the word line bonding region WLBA, the upper bonding metal 870b may be formed in the first cell region CELL1, and the upper bonding metal 770b may be formed in the peripheral circuit region PERI. The upper bonding metal 870b of the first cell region CELL1 and the upper bonding metal 770b of the peripheral circuit region PERI may be electrically connected to each other by a bonding method. The upper bonding metal 870b and the upper bonding metal 770b may be formed of aluminum, copper, or tungsten.

In the external pad bonding region PA, a lower metal pattern 871e may be formed on a lower portion of the first cell region CELL1, and an upper metal pattern 972a may be formed on an upper portion of the second cell region CELL2. The lower metal pattern 871e of the first cell region CELL1 and the upper metal pattern 972a of the second cell region CELL2 may be connected by a bonding method in the external pad bonding region PA. Likewise, an upper metal pattern 872a may be formed on an upper portion of the first cell region CELL1, and an upper metal pattern 772a may be formed on an upper portion of the peripheral circuit region PERI. The upper metal pattern 872a of the first cell region CELL1 and the upper metal pattern 772a of the peripheral circuit region PERI may be connected to each other by a bonding method.

Common source line contact plugs 880 and 980 may be disposed in the external pad bonding region PA. The common source line contact plugs 880 and 980 may be formed of a conductive material, such as metal, a metal compound, or doped poly-silicon. The common source line contact plug 880 of the first cell region CELL1 may be electrically connected with the common source line 820, and the common source line contact plug 980 of the second cell region CELL2 may be electrically connected with the common source line 920. A first metal line 850a and a second metal line 860a may be sequentially stacked on an upper portion of the common source line contact plug 880 of the first cell region CELL1, and a first metal line 950a and a second metal line 960a may be sequentially stacked on an upper portion of the common source line contact plug 980 of the second cell region CELL2.

Input/output pads 705, 905, and 906 may be disposed in the external pad bonding region PA. Referring to FIG. 16, a lower insulating layer 701 may cover a lower surface of the first substrate 710, and the first input/output pad 705 may be formed on the lower insulating layer 701. The first input/output pad 705 may be connected with at least one of the plurality of circuit elements 720a disposed in the peripheral circuit region PERI through a first input/output contact plug 703 and may be separated from the first substrate 710 by the lower insulating layer 701. In addition, a side insulating layer may be disposed between the first input/output contact plug 703 and the first substrate 710 and may electrically isolate the first input/output contact plug 703 from the first substrate 710.

An upper insulating layer 901 may be formed on the third substrate 910 to cover the upper surface of the third substrate 910. The second input/output pad 905 and/or the third input/output pad 906 may be disposed on the upper insulating layer 901. The second input/output pad 905 may be connected with at least one of the plurality of circuit elements 720a disposed in the peripheral circuit region PERI through second input/output contact plugs 903 and 803, and the third input/output pad 906 may be connected with at least one of the plurality of circuit elements 720a disposed in the peripheral circuit region PERI through third input/output contact plugs 904 and 804.

In some embodiments, the third substrate 910 may not be disposed in the regions in which the input/output contact plugs are disposed. For example, as illustrated in B, the third input/output contact plug 904 may be separated from the third substrate 910 in a direction parallel to the upper surface of the third substrate 910, may penetrate (i.e., extend into) an interlayer insulating layer 915 of the second cell region CELL2, and may be connected to the third input/output pad 906. In this case, the third input/output contact plug 904 may be formed through various processes.

For example, as illustrated in B1, the third input/output contact plug 904 may extend in the third direction (the Z-axis direction) and may have an increasing diameter toward the upper insulating layer 901. That is, while the channel structure CH described with reference to A1 has a decreasing diameter toward the upper insulating layer 901, the third input/output contact plug 904 may have an increasing diameter toward the upper insulating layer 901. For example, the third input/output contact plug 904 may be formed after the second cell region CELL2 and the first cell region CELL1 are coupled by a bonding method.

For example, as illustrated in B2, the third input/output contact plug 904 may extend in the third direction (the Z-axis direction) and may have a decreasing diameter toward the upper insulating layer 901. That is, likewise to the channel structure CH, the third input/output contact plug 904 may have a decreasing diameter toward the upper insulating layer 901. For example, the third input/output contact plug 904 may be formed together with the cell contact plugs 940 before the second cell region CELL2 and the first cell region CELL1 are coupled by a bonding method.

In some embodiments, an input/output contact plug may be disposed to overlap the third substrate 910. For example, as illustrated in C, the second input/output contact plug 903 may be formed through the interlayer insulating layer 915 of the second cell region CELL2 in the third direction (the Z-axis direction) and may be electrically connected to the second input/output pad 905 through the third substrate 910. In this case, a connection structure of the second input/output contact plug 903 and the second input/output pad 905 may be implemented in various ways.

For example, as illustrated in C1, an opening 908 may be formed through the third substrate 910, and the second input/output contact plug 903 may be directly connected to the second input/output pad 905 through the opening 908 formed in the third substrate 910. In this case, as illustrated in C1, the second input/output contact plug 903 may have an increasing diameter toward the second input/output pad 905. However, this is illustrative, and, in some embodiments, the second input/output contact plug 903 may have a decreasing diameter toward the second input/output pad 905.

For example, as illustrated in C2, the opening 908 may be formed through the third substrate 910, and a contact 907 may be formed in the opening 908. One end portion of the contact 907 may be connected to the second input/output pad 905, and an opposite end portion of the contact 907 may be connected to the second input/output contact plug 903. Accordingly, the second input/output contact plug 903 may be electrically connected to the second input/output pad 905 through the contact 907 in the opening 908. In this case, as illustrated in C2, the contact 907 may have an increasing diameter toward the second input/output pad 905, and the second input/output contact plug 903 may have a decreasing diameter toward the second input/output pad 905. For example, the second input/output contact plug 903 may be formed together with the cell contact plugs 940 before the second cell region CELL2 and the first cell region CELL1 are coupled by a bonding method, and the contact 907 may be formed after the second cell region CELL2 and the first cell region CELL1 are coupled by the bonding method.

For example, as illustrated in C3, a stopper 909 may be additionally formed on an upper surface of the opening 908 of the third substrate 910. The stopper 909 may be a metal line formed on the same layer as the common source line 920. However, this is illustrative, and the stopper 909 may be a metal line formed on the same layer as at least one of the word lines 930. The second input/output contact plug 903 may be electrically connected to the second input/output pad 905 through the contact 907 and the stopper 909.

Meanwhile, similarly to the second and third input/output contact plugs 903 and 904 of the second cell region CELL2, the second and third input/output contact plugs 803 and 804 of the first cell region CELL1 may have a decreasing diameter toward the lower metal pattern 871e, or may have an increasing diameter toward the lower metal pattern 871e.

Meanwhile, in some embodiments, a slit 911 may be formed in the third substrate 910. For example, the slit 911 may be formed at any position in the external pad bonding region PA. For example, as illustrated in D, the slit 911 may be located between the second input/output pad 905 and the cell contact plugs 940 when viewed on a plane (e.g., a plan view). However, this is illustrative, and the slit 911 may be formed such that the second input/output pad 905 is located between the slit 911 and the cell contact plugs 940 when viewed on the plane.

For example, as illustrated in D1, the slit 911 may be formed through the third substrate 910. For example, the slit 911 may be used to prevent the third substrate 910 from being finely cracked when the opening 908 is formed. However, this is illustrative, and the slit 911 may be formed to have a depth ranging from about 60% to about 70% of the thickness of the third substrate 910.

For example, as illustrated in D2, a conductive material 912 may be formed in the slit 911. For example, the conductive material 912 may be used to discharge a leakage current generated while circuit elements in the external pad bonding region PA are driven. In this case, the conductive material 912 may be connected to an external ground line.

For example, as illustrated in D3, an insulating material 913 may be formed in the slit 911. For example, the insulating material 913 may be formed to electrically isolate the second input/output pad 905 and the second input/output contact plug 903 disposed in the external pad bonding region PA from the word line bonding region WLBA. An influence of a voltage provided through the second input/output pad 905 on a metal layer disposed on the third substrate 910 in the word line bonding region WLBA may be interrupted by forming the insulating material 913 in the slit 911.

Meanwhile, in some embodiments, the first to third input/output pads 705, 905, and 906 may be selectively formed. For example, the semiconductor device 1000 may be implemented to include only the first input/output pad 705 disposed on the lower insulating layer 701, only the second input/output pad 905 disposed on the third substrate 910, or only the third input/output pad 906 disposed on the upper insulating layer 901.

Meanwhile, in some embodiments, at least one of the second substrate 810 of the first cell region CELL1 or the third substrate 910 of the second cell region CELL2 may be used as a sacrificial substrate and may be completely or partially removed before or after a bonding process. An additional layer may be stacked after the removal of the substrate. For example, the second substrate 810 of the first cell region CELL1 may be removed before or after the peripheral circuit region PERI and the first cell region CELL1 are bonded to each other, and an insulating layer for covering an upper surface of the common source line 820 or a conductive layer for connection may be formed. Similarly, the third substrate 910 of the second cell region CELL2 may be removed before or after the first cell region CELL1 and the second cell region CELL2 are bonded to each other, and the upper insulating layer 901 for covering an upper surface of the common source line 920 or a conductive layer for connection may be formed.

For example, bonding metal patterns may be the limited connecting elements. The limited number of bonding metal patterns may be provided in a limited area (e.g., limited locations). The electronic device 100 may calculate the availability of bonding metal patterns of the lower chip including the peripheral circuit region PERI based on the circuit schematics of the semiconductor device 1000 and may generate the layout image LO when the availability indicates that the PnR is available.

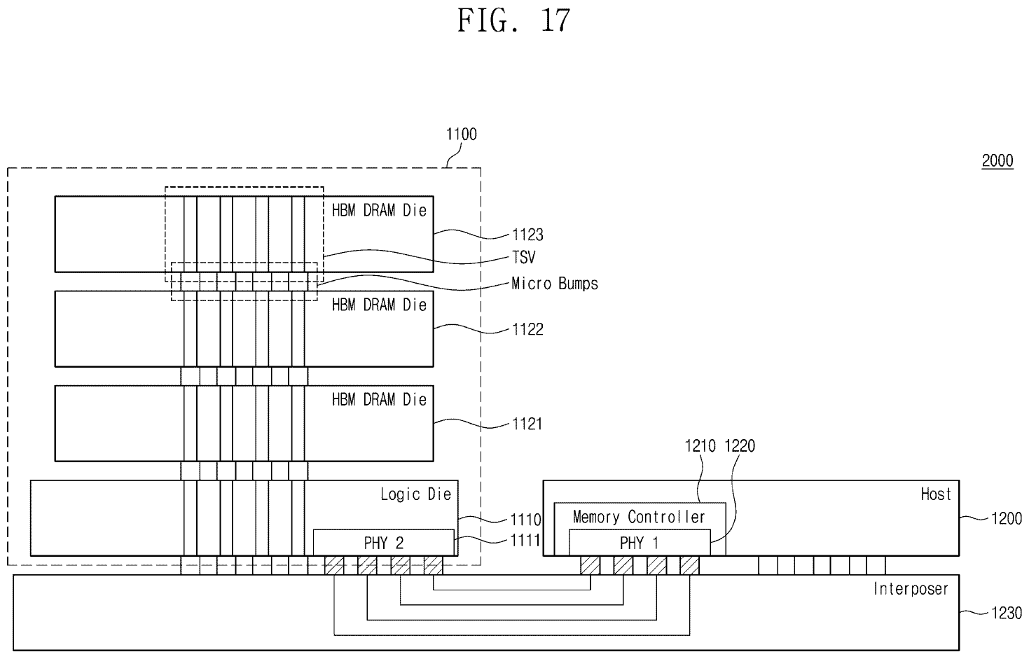

FIG. 17 is a view illustrating a semiconductor device 2000 according to some embodiments of the present disclosure. Referring to FIG. 17, the semiconductor device 2000 may include a memory device 1100, a host 1200, a memory controller 1210, and an interposer 1230.

The memory device 1100 may include first to third memory dies (e.g., high bandwidth memory (HBM) DRAM dies) 1121 to 1123 and a logic die 1110. The first to third memory dies 1121 to 1123 may be sequentially stacked on the logic die 1110 in a vertical direction.

The first to third memory dies 1121 to 1123 and the logic die 1110 may be electrically connected to each other through micro bumps and through silicon vias (TSVs) arranged in a matrix form. However, locations of the through silicon vias and the micro bumps are not limited to the example illustrated in FIG. 17.

The first to third memory dies 1121 to 1123 may be manufactured to have the same structure/configuration. An example in which the number of memory dies included in the memory device 1100 is three is illustrated in FIG. 17, but the number of memory dies is not limited thereto. In some embodiments, a memory die may be also referred to as a “core die” or a “slave die”, and a die may be also referred to as a “chip”

The logic die 1110 may communicate with a device located outside the memory device 1100 (e.g., may communicate with a device external to the memory device 1100). For example, the device may be the host 1200. In some embodiments, the host 1200 may be referred to as a “system on chip (SoC)”. The logic die 1110 may include a second physical layer (PHY 2) 1111 electrically connected to the host 1200 and may communicate with the host 1200 based on the second physical layer 1111.

The logic die 1110 may provide an address and data transmitted from the host 1200 to the first to third memory dies 1121 to 1123. The logic die 1110 may receive data from the first to third memory dies 1121 to 1123.

The logic die 1110 may provide an interface between the first to third memory dies 1121 to 1123 and the host 1200. The logic die 1110 may be referred to as an “interface die”, a “master die”, or a “buffer die”.

The memory device 1100 may be a general-purpose DRAM device such as a DDR SDRAM (Double Data Rate Synchronous Dynamic Random Access Memory), a DDR2 SDRAM, a DDR3 SDRAM, a DDR4 SDRAM, or a DDR5 SDRAM. The memory device 1100 may be a mobile DRAM device such as an LPDDR (Low Power Double Data Rate) SDRAM, an LPDDR2 SDRAM, an LPDDR3 SDRAM, an LPDDR4 SDRAM, an LPDDR4X SDRAM, or an LPDDR5 SDRAM. However, the memory device 1100 illustrated in FIG. 17 is not limited thereto.

The host 1200 may include a processor (not illustrated) capable of performing various operations (or calculations) for the purpose of an application that the semiconductor device 2000 supports. For example, the host 1200 may include at least one of a CPU (Central Processing Unit), an ISP (Image Signal Processing Unit), a DSP (Digital Signal Processing Unit), a GPU (Graphics Processing Unit), a VPU (Vision Processing Unit), or an NPU (Neural Processing Unit).

The host 1200 may include the memory controller 1210 and a first physical layer (PHY 1) 1220 electrically connected to the logic die 1110 and may communicate with the logic die 1110 based on the first physical layer 1220. The host 1200 may store data necessary for processing in the memory device 1100 or may read data necessary for processing from the memory device 1100. However, a location of the memory controller 1210 is not limited to the example illustrated in FIG. 17.

The interposer 1230 may connect the memory device 1100 and the host 1200. In detail, the interposer 1230 may provide physical paths that connect the memory device 1100 and the host 1200 and are formed by using conductive materials for electrical connection. For example, the interposer 1230 may be a silicon interposer. However, the interposer 1230 illustrated in FIG. 17 is not limited thereto.

For example, the TSVs may be the limited connecting elements. The limited number of TSVs may be provided. The electronic device 100 may calculate the availability of bonding metal patterns of the logic die 1110 (or the first to third memory dies 1121 to 1123) based on the circuit schematics of the semiconductor device 2000 and may generate the layout image LO when the availability indicates that the PnR is available.

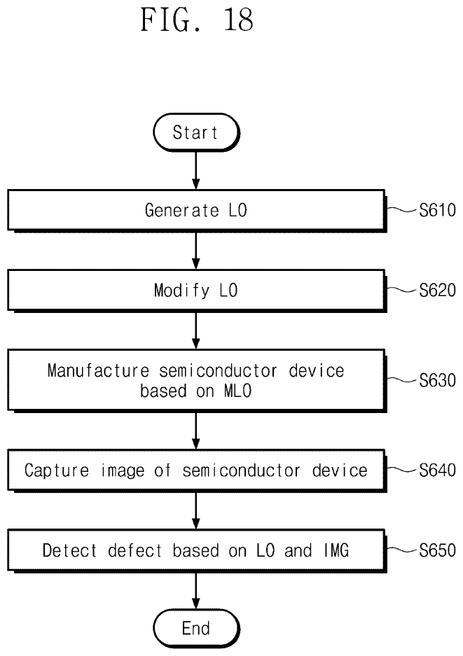

FIG. 18 illustrates an example of a method in which the semiconductor manufacturing system 10 manufactures semiconductor devices. Referring to FIGS. 1 and 18, in operation S610, the semiconductor manufacturing system 10 may generate the layout image LO. For example, the layout generation module 11 may generate the layout image LO. For example, the layout generation module 11 may partition circuit components of the circuit schematics into mats and may calculate the availability of limited connecting elements and areas of the partitioned circuit components. When the availability indicates that the PnR is available, the layout generation module 11 may generate the layout image LO. When the availability indicates that the PnR is unavailable, the layout generation module 11 may repeat the ungrouping of a circuit component of the circuit schematics, the partitioning, and the calculating of the availability until the availability indicates “available”.

In operation S620, the semiconductor manufacturing system 10 may modify the layout image LO. For example, the modification module 12 may generate the modified layout image MLO from the layout image LO. The modified layout image MLO may reflect, for example, the PPC, the OPC, or the PPC and the OPC.

In operation S630, the semiconductor manufacturing system 10 may manufacture semiconductor devices by using the modified layout image MLO. For example, the manufacture device 13 may receive the modified layout image MLO from the modification module 12. The manufacture device 13 may manufacture the semiconductor devices by applying the processes PRC to the wafer WAF.

In operation S640, the semiconductor manufacturing system 10 may capture an image of a semiconductor device. For example, the imaging device 14 may generate the captured image IMG by capturing an image of the wafer WAF to which the processes PRC are applied.

In operation S650, the semiconductor manufacturing system 10 may detect defects based on the layout image LO and the captured image IMG. For example, the defect detection module 16 may compare the layout image LO and the captured image IMG and may determine whether the captured image IMG coincides with the design of the layout image LO. When the captured image IMG coincides with the design of the layout image LO, the semiconductor devices may be shipped. When the captured image IMG does not coincide with the design of the layout image LO, the semiconductor devices may be determined as defective products and may not be shipped.

In the above embodiments, some components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

In the above embodiments, some components according to the present disclosure are referenced by using blocks. The blocks may be implemented with various hardware devices, such as an integrated circuit (IC), an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to embodiments of the present disclosure, an electronic device may in advance verify whether limited connecting elements of a semiconductor device satisfy limits applied to the process of manufacturing the semiconductor device. Accordingly, an electronic device capable of decreasing a time necessary for the generation of a layout image and an operating method of the electronic device are provided.

While the present disclosure has been described with reference to example embodiments thereof, it will be apparent to those of ordinary skill in the art that various changes and modifications may be made thereto without departing from the scope of the present disclosure as set forth in the following claims.

What is claimed is:

1. An operating method of an electronic device that includes a processor and is configured to support manufacture of a semiconductor device, the method comprising:
receiving, at the processor, circuit schematics for the manufacture of the semiconductor device;
partitioning, at the processor, circuit components of the circuit schematics into at least two mats;
calculating, at the processor, availability of placement and routing (PnR) of the circuit components, based on limited connecting elements that are configured to be electrically connected to the circuit components, for each of the at least two mats; and
performing, at the processor, the placement and routing to generate a layout image for the manufacture of the semiconductor device when the availability of the placement and routing that was calculated indicates that the placement and routing is available,
wherein the limited connecting elements include vertical lines, which are configured to electrically connect an upper portion and a lower portion of the semiconductor device, at limited locations of the semiconductor device.

2. The method of claim 1, wherein partitioning the circuit components of the circuit schematics into the at least two mats comprises:
counting a number of lower-level circuit components included in each of the circuit components; and
partitioning the circuit components into the at least two mats based on counts of the lower-level circuit components.

3. The method of claim 2, wherein partitioning the circuit components into the at least two mats based on the counts of the lower-level circuit components comprises:
partitioning the circuit components into first and second mats of the at least two mats such that a sum of the counts of the lower-level circuit components included in the first mat and a sum of the counts of the lower-level circuit components included in the second mat approximate.

4. The method of claim 2, wherein counting the number of the lower-level circuit components included in each of the circuit components comprises:
counting the number of the lower-level circuit components of an immediately underlying level included in each of the circuit components.

5. The method of claim 2, wherein counting the number of the lower-level circuit components included in each of the circuit components comprises:
counting the number of the lower-level circuit components of two or more lower levels included in each of the circuit components.

6. The method of claim 1, wherein calculating the availability of the placement and routing of the circuit components comprises:
counting interconnections between the at least two mats.

7. The method of claim 6, wherein calculating the availability of the placement and routing of the circuit components further comprises:
determining that the placement and routing is unavailable when a count of the interconnections between the at least two mats is greater than a first threshold value, and
wherein the first threshold value is a number of the limited connecting elements allowed in each of the at least two mats.

8. The method of claim 6, wherein calculating the availability of the placement and routing of the circuit components further comprises:
determining that the placement and routing is unavailable when an area of the circuit components included in each of the at least two mats is larger than an area allowed in each of the at least two mats.

9. The method of claim 1, further comprising:
ungrouping one of the circuit components to a lower level when the availability of the placement and routing that was calculated indicates that the placement and routing is unavailable.

10. The method of claim 9, wherein ungrouping the one of the circuit components to the lower level comprises:
ungrouping the one of the circuit components to an immediately underlying level.

11. The method of claim 9, wherein each of the circuit components has a count of lower-level circuit components included therein, and
wherein the count of the one of the circuit components is higher than the count of each of remaining ones of the circuit components.

12. The method of claim 11, wherein the count of the lower-level circuit components is a number of the lower-level circuit components of an immediately underlying level included in each of the circuit components.

13. The method of claim 11, wherein the count of the lower-level circuit components is a number of the lower-level circuit components of two or more lower levels included in each of the circuit components.

14. The method of claim 9, further comprising:
partitioning the circuit components of the circuit schematics into the at least two mats and calculating the availability of the placement and routing of the circuit components, after ungrouping the one of the circuit components.

15. The method of claim 1, wherein the semiconductor device comprises a nonvolatile memory device that includes a peripheral circuit and a cell array on the peripheral circuit and is configured to be manufactured in a cell over peripheral (COP) method, and
wherein the limited connecting elements include through hole vias (THVs) that are configured to extend into a substrate of the cell array.

16. The method of claim 1, wherein the semiconductor device comprises a nonvolatile memory device that includes a peripheral circuit and a cell array and is configured to be manufactured in a bonding method, and
wherein the limited connecting elements include lines that are configured to bond the peripheral circuit and the cell array.

17. The method of claim 1, wherein the limited connecting elements include through silicon vias (TSVs) that are configured to extend into the semiconductor device.

18. An operating method of an electronic device that includes a processor and is configured to support manufacture of a semiconductor device, the method comprising:
receiving, at the processor, circuit schematics for the manufacture of the semiconductor device;
partitioning, at the processor, circuit components of the circuit schematics into at least two mats;
calculating, at the processor, availability of placement and routing (PnR) of the circuit components, based on limited connecting elements that are configured to be electrically connected to the circuit components, for each of the at least two mats;
performing, at the processor, the placement and routing to generate a layout image for the manufacture of the semiconductor device when the availability of the placement and routing that was calculated indicates that the placement and routing is available; and
ungrouping one of the circuit components to a lower level when the availability of the placement and routing that was calculated indicates that the placement and routing is unavailable,
wherein the limited connecting elements include vertical lines, which are configured to electrically connect an upper portion and a lower portion of the semiconductor device, at limited locations of the semiconductor device, and
wherein calculating the availability of the placement and routing of the circuit components includes counting interconnections between the at least two mats.

19. The method of claim 18, further comprising:
partitioning the circuit components of the circuit schematics into the at least two mats and calculating the availability of the placement and routing of the circuit components, after ungrouping the one of the circuit components.

20. An electronic device configured to support manufacture of a semiconductor device, the electronic device comprising:
a processor; and
a memory configured to store circuit schematics for the manufacture of the semiconductor device,
wherein the processor is configured to:
partition circuit components of the circuit schematics into at least two mats;
calculate availability of placement and routing (PnR) of the circuit components, based on limited connecting elements that are configured to be electrically connected to the circuit components, for each of the at least two mats; and
perform the placement and routing to generate a layout image for the manufacture of the semiconductor device when the availability of the placement and routing that was calculated indicates that the placement and routing is available, and
wherein the limited connecting elements include vertical lines, which are configured to electrically connect an upper portion and a lower portion of the semiconductor device, at limited locations of the semiconductor device.
